(19) United States
(12) Patent Application Publication
(10) Pub. No.: US 2026/0101585 A1
(43) Pub. Date: Apr. 9, 2026

(54) ELECTRONIC DEVICE AND METHOD FOR MANUFACTURING THE SAME

(71) Applicant: Samsung Display Co., Ltd., Yongin-si (KR)

(72) Inventors: Hyunmo LEE, Yongin-si (KR); CHULWON PARK, Yongin-si (KR); SANGWOO SOHN, Yongin-si (KR); JUN HYUNG LIM, Yongin-si (KR); Hyunjun JEONG, Yongin-si (KR); KUNHEE JO, Yongin-si (KR)

(73) Assignee: Samsung Display Co., Ltd., Yongin-si (KR)

(21) Appl. No.: 19/244,419

(22) Filed: Jun. 20, 2025

(30) Foreign Application Priority Data
Oct. 8, 2024 (KR) 10-2024-0137064

(51) Int. Cl. H10D 86/40; H10D 86/01; H10D 86/60

(52) U.S. Cl. CPC H10D 86/431; H10D 86/0221; H10D 86/60

(57) ABSTRACT

An electronic device includes a first transistor disposed on a substrate and including a first semiconductor pattern and a first gate, and a buffer layer. The buffer layer includes a first part overlapping the first semiconductor pattern in a plan view and having a first thickness, and a second part connected to the first part and having a second thickness, the second thickness and the first thickness being different from each other.

### CROSS-REFERENCE TO RELATED APPLICATION(S)

This application claims priority to and benefits of Korean Patent Application No. 10-2024-0137064 under 35 U.S.C. § 119, filed on Oct. 8, 2024, in the Korean Intellectual Property Office (KIPO), the entire contents of which are incorporated herein by reference.

### BACKGROUND

### 1. Technical Field

Embodiments of the disclosure described herein relate to an electronic device with an improved reliability and a method for manufacturing the same.

### 2. Description of the Related Art

Display devices are used in various multimedia devices, such as televisions, mobile phones, tablet computers, and game consoles, to provide image information to users. The display device includes a light emitting element and a pixel circuit for driving the light emitting element. In addition, the display device includes a gate driving circuit for providing signals to the pixel circuit. Light emission of the light emitting elements is controlled by signals that are output from the gate driving circuit.

The display panel may include a pixel including a light emitting element and a pixel driver that drives the light emitting elements, and a driver that drives the pixels. The driver may include a scan driver and a data driver. The scan driver may be mounted on a substrate together with the pixels to be provided.

### SUMMARY

Embodiments of the disclosure provide an electronic device with an improved reliability.

According to an embodiment, an electronic device may include a first transistor disposed on a substrate and including a first semiconductor pattern and a first gate, and a buffer layer. The buffer layer may include a first part overlapping the first semiconductor pattern in a plan view and having a first thickness, and a second part connected to the first part and having a second thickness, the second thickness and the first thickness being different from each other.

The buffer layer may include a plurality of layers, and at least one of the plurality of layers may not overlap the first part in a plan view.

The plurality of layers may include a lower oxide layer, a nitride layer disposed on the lower oxide layer, and an upper oxide layer disposed on the nitride layer. The lower oxide layer and the nitride layer may not overlap the first part in a plan view.

The electronic device may further include an opening passing through the lower oxide layer and the nitride layer. The first semiconductor pattern may be disposed in the opening and contact the upper oxide layer.

The plurality of layers may include a lower oxide layer and a nitride layer disposed on the lower oxide layer, and the nitride layer may not overlap the first part in a plan view.

The first semiconductor pattern may contact the lower oxide layer.

The buffer layer may be a single layer, and a recessed part overlapping the first part in a plan view may be defined in the buffer layer.

The buffer layer may include silicon oxide.

The electronic device may further include a lower conductive layer including lower conductive patterns disposed on the substrate. One of the lower conductive patterns may be electrically connected to the first semiconductor pattern.

The electronic device may further include a second transistor including a second semiconductor pattern spaced apart from the first semiconductor pattern and a second gate overlapping the second semiconductor pattern in a plan view. The first part may include a plurality of parts spaced apart from each other, and each of the first semiconductor pattern and the second semiconductor pattern may be disposed in one of the plurality of parts.

Another one of the lower conductive patterns may overlap the second semiconductor pattern in a plan view and may be insulated from the second semiconductor pattern.

The second transistor may not overlap the lower conductive patterns in a plan view.

A thickness of a portion of the buffer layer, which overlaps the second transistor, and the second thickness may be different from each other.

The second part may include a portion overlapping another one of the lower conductive patterns in a plan view.

According to an embodiment, a method for manufacturing an electronic device may include providing a substrate including a first area and a second area, forming lower conductive patterns on the substrate, forming an initial buffer layer covering the lower conductive patterns, forming a buffer layer by removing at least a portion of the initial buffer layer, which overlaps the first area in a plan view such that portions of the lower conductive patterns are exposed, forming a semiconductor pattern in the first area, and forming a gate overlapping the semiconductor pattern in a plan view.

The forming of the buffer layer may include forming a recessed part overlapping the first area in a plan view in the buffer layer.

The forming of the initial buffer layer may include forming a lower oxide layer, and forming a nitride layer on the lower oxide layer, and the forming of the buffer layer may include forming an opening overlapping the first area in a plan view in the nitride layer.

A material constituting the lower oxide layer may have a higher etch selectivity than a material constituting the nitride layer.

The method may further include forming an upper oxide layer on the nitride layer. The upper oxide layer may be formed to overlap the first area and the second area in a plan view, and the semiconductor pattern may be formed by forming a semiconductor material on the upper oxide layer and patterning the semiconductor material such that the semiconductor material overlaps the opening in a plan view.

The forming of the buffer layer may include removing at least a portion of the initial buffer layer in the first area through a dry etching process.

### BRIEF DESCRIPTION OF THE DRAWINGS

The above and other objects and features of the disclosure will become apparent by describing embodiments with reference to the accompanying drawings.

FIG. 1A is a perspective view of an electronic device according to an embodiment of the disclosure.

FIG. 1B is a schematic block diagram of an electronic device according to an embodiment of the disclosure.

FIG. 2 is a schematic cross-sectional view of the electronic device illustrated in FIG. 1A according to an embodiment.

FIG. 3 is a schematic cross-sectional view of a display panel illustrated in FIG. 2 according to an embodiment.

FIG. 4 is a schematic block diagram of the electronic device illustrated in FIG. 1.

FIG. 5 is a schematic diagram of an equivalent circuit of one of pixels according to an embodiment of the disclosure.

FIGS. 6A and 6B are schematic cross-sectional views of a display panel according to an embodiment of the disclosure.

FIG. 7 is a schematic cross-sectional view of a display panel according to an embodiment of the disclosure.

FIG. 8 is a schematic cross-sectional view of a display panel according to an embodiment of the disclosure.

FIG. 9 is a schematic cross-sectional view of a display panel according to an embodiment of the disclosure.

FIG. 10 is a schematic cross-sectional view of a display panel according to an embodiment of the disclosure.

FIG. 11 is a schematic cross-sectional view of a display panel according to an embodiment of the disclosure.

FIGS. 12A to 12J are schematic cross-sectional views illustrating a method for manufacturing a display panel according to an embodiment of the disclosure.

FIGS. 13A and 13B are schematic cross-sectional views illustrating a method for manufacturing a display panel according to an embodiment of the disclosure.

FIGS. 14A to 14C are schematic cross-sectional views illustrating a method for manufacturing a display panel according to an embodiment of the disclosure.

### DETAILED DESCRIPTION OF THE EMBODIMENTS

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The same reference numerals denote the same components. Furthermore, in the drawings, thicknesses, ratios, dimensions of the components are exaggerated for an effective description of the technical contents.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure. A singular expression includes a plural expression unless an exemption is explicitly described in the context.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined, all terms, including technical and scientific terms, used herein have the same meaning as commonly understood by those skilled in the art to which the disclosure pertains. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein.

Hereinafter, embodiments of the disclosure will be described with reference to the drawings.

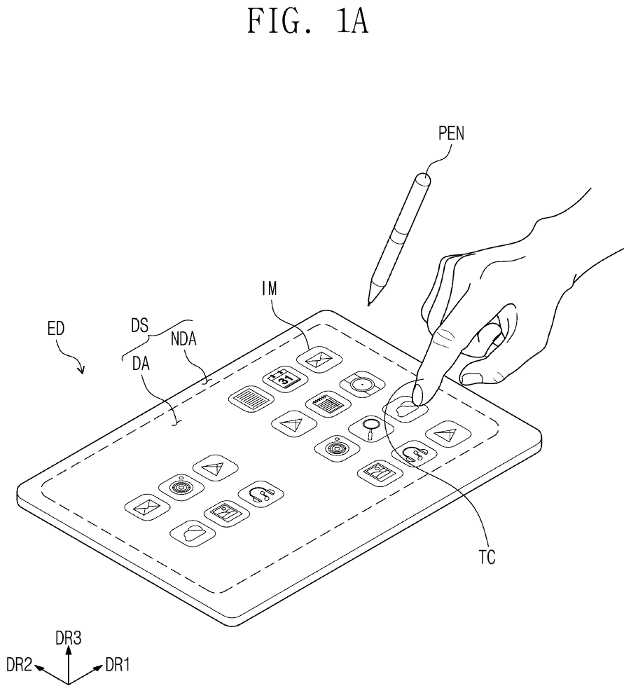

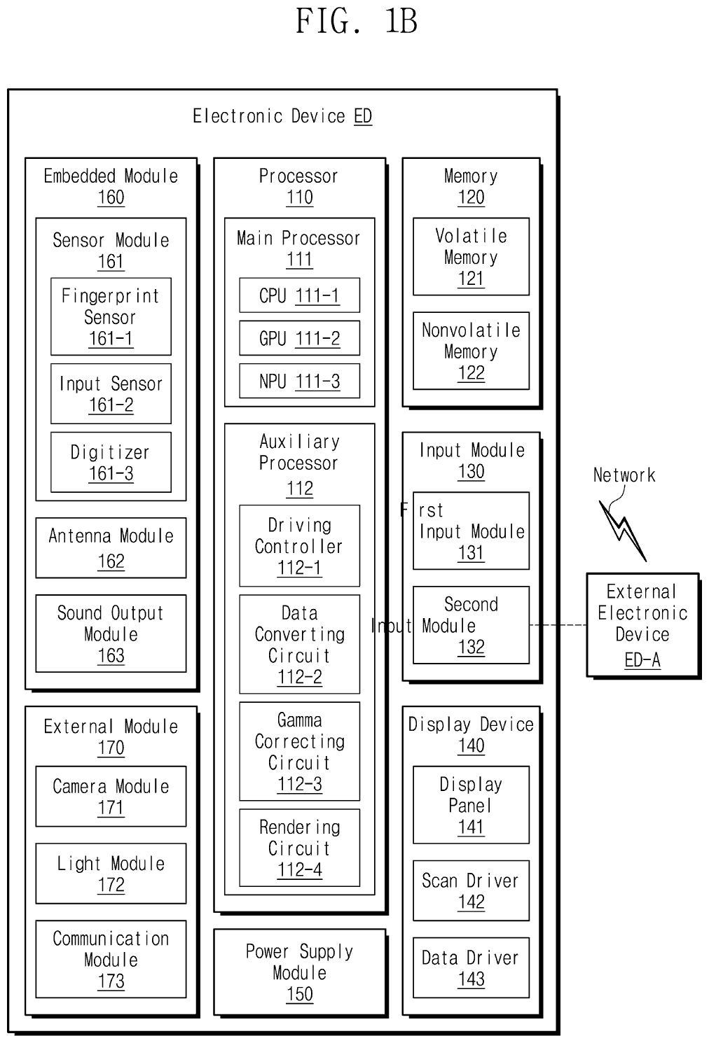

FIG. 1A is a perspective view of an electronic device according to an embodiment of the disclosure. FIG. 1B is a schematic block diagram of an electronic device according to an embodiment of the disclosure.

Referring to FIG. 1A, an electronic device ED may include long sides that extend in parallel to a first direction DR1 and short sides that extend in parallel to a second direction DR2 that intersects the first direction DR1. However, the disclosure is not limited thereto, and in another embodiment, the electronic device ED may include sides having a same length with respect to each of the first and second directions DR1 and DR2.

Hereinafter, a direction that is substantially perpendicular to a plane defined by the first direction DR1 and the second direction DR2 is defined as a third direction DR3. Furthermore, in the specification, a meaning of “when viewed on a plane” or “in a plan view” is defined as a state, in which it is viewed from the third direction DR3.

A front surface of the electronic device ED may be defined as a display surface DS, and may have a plane defined by a first direction DR1 and a second direction DR2. An image IM that is generated by the electronic device ED may be provided to the user through the display surface DS.

The display surface DS may include a display area DA and a non-display area NDA adjacent to the display area DA. The display area DA may be an area, in which an image is displayed, and the non-display area NDA may be an area, in which an image is not displayed. The non-display area NDA may be adjacent to at least one side of the display area DA. In an embodiment, the non-display area NDA may have a frame shape that surrounds the display area DA in a plan view. However, the disclosure is not limited thereto, and in another embodiment of the disclosure, the non-display area NDA may be omitted, and the display surface DS may include only the display area DA.

The electronic device ED may sense inputs that are applied from the outside of the electronic device ED. For example, the electronic device ED may sense a first input by a touch TC and a second input by a touch pen PEN. The first input by the touch TC may include various types of external inputs, such as a part of the user's body, light, heat, or a pressure. The touch pen PEN may be an active pen or an electromagnetic pen, but the disclosure is not limited thereto. The touch pen PEN may be an input device, and the display area DA may provide a sensing area that may sense an input to a user, in addition to displaying an image.

Referring to FIG. 1B, an electronic device ED may output a variety of information through a display module 140 in an operating system. In case that a processor 110 executes an application stored in a memory 120, the display module 140 may provide the user with application information through a display panel 141.

The processor 110 may obtain an external input through an input module 130 or a sensor module 161 and execute an application corresponding to the external input. For example, in case that the user selects a camera icon displayed in the display panel 141, the processor 110 may obtain the user input through an input sensor 161-2 and activate a camera module 171. The processor 110 may transfer image data corresponding to a photographed image obtained through the camera module 171 to the display module 140. The display module 140 may display an image corresponding to the photographed image through the display panel 141.

The operation of the electronic device ED is briefly described above. Below, a configuration of the electronic device ED will be described in detail. Some of components of the electronic device ED described below may be integrally implemented in one component, and the component may be divided into two or more components.

Referring to FIG. 1B, the electronic device ED may communicate with an external electronic device ED-A over a network (e.g., a short-range wireless communication network or a long-range wireless communication network). According to an embodiment, the electronic device ED may include the processor 110, the memory 120, the input module 130, the display module 140, a power module 150, an embedded module (or an internal module) 160, and an external module 170. In another embodiment, the electronic device ED may not include at least one of the above components or may further include one or more other components. According to an embodiment, some of the above components (e.g., the sensor module 161, an antenna module 162, or a sound output module 163) may be integrated into another component (e.g., the display module 140).

The processor 110 may execute software to control at least one component (e.g., a hardware or software component) of the electronic device ED connected with the processor 110 and may perform various data processing or operations. According to an embodiment, as at least a part of the data processing or operations, the processor 110 may store a command or data received from another component (e.g., the input module 130, the sensor module 161, or a communication module 173) in a volatile memory 121, may process the command or data stored in the volatile memory 121, and may store the processed data in a nonvolatile memory 122.

The processor 110 may include a main processor 111 and an auxiliary processor 112. The main processor 111 may include at least one of a central processing unit (CPU) 111-1 and an application processor (AP). The main processor 111 may further include at least one of a graphic processing unit (GPU) 111-2, a communication processor (CP), and an image signal processor (ISP). The main processor 111 may further include a neural processing unit (NPU) 111-3. The neural processing unit 111-3 may be a processor specialized for processing of an artificial intelligence model, and the artificial intelligence model may be created through machine learning. The artificial intelligence model may include multiple artificial neural network layers. The artificial neural network may include at least one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, and a combination thereof, but the disclosure is not limited thereto. In an embodiment, the artificial intelligence model may include a software structure in addition to a hardware structure. At least two of the above processing units and processors may be integrally implemented in one component (e.g., a single chip), or each of the above processing units and processors may be implemented in an independent component (e.g., multiple chips).

The auxiliary processor 112 may include a controller 112-1. The controller 112-1 may include an interface conversion circuit and a timing control circuit. The controller 112-1 may receive an image signal from the main processor 111 and output image data obtained by converting a data format of the image signal suitable for the specification of an interface with the display module 140. The controller 112-1 may output various kinds of control signals to drive the display module 140.

The auxiliary processor 112 may further include a data conversion circuit 112-2, a gamma correction circuit 112-3, a rendering circuit 112-4, etc. The data conversion circuit 112-2 may receive image data from the driving controller 112-1, and the data conversion circuit 112-2 may compensate the image data such that an image is displayed with a desired luminance depending on a characteristic of the electronic device ED or user settings or may convert the image data to reduce power consumption or to compensate for afterimages. The gamma correction circuit 112-3 may convert the image data or the gamma reference voltage such that an image displayed on the electronic device ED has a desired gamma characteristic. The rendering circuit 112-4 may receive the image data from the controller 112-1 and may render the image data in consideration of a pixel arrangement of the display panel 141 applied to the electronic device ED. At least one of the data conversion circuit 112-2, the gamma correction circuit 112-3, and the rendering circuit 112-4 may be integrated into another component (e.g., the main processor 111 or the controller 112-1). At least one of the data conversion circuit 112-2, the gamma correction circuit 112-3, and the rendering circuit 112-4 may be integrated into a data driver 143 described below.

The memory 120 may store various data used by at least one component (e.g., the processor 110 or the sensor module 161) of the electronic device ED and input data or output data for commands related thereto. The memory 120 may include at least one of the volatile memory 121 and the nonvolatile memory 122.

The input module 130 may receive a command or data to be used by a component (e.g., the processor 110, the sensor module 161, or the sound output module 163) of the electronic device ED from the outside of the electronic device ED (e.g., the user or the external electronic device ED-A).

The input module 130 may include a first input module 131 to which a command or data are input from the user and a second input module 132 to which a command or data are input from the external electronic device ED-A. The first input module 131 may include a microphone, a mouse, a keyboard, a key (e.g., a button), or a pen (e.g., a passive pen or an active pen). The second input module 132 may support a specified protocol capable of connecting to the external electronic device ED-A by wire or wirelessly. According to an embodiment, the second input module 132 may include a high definition multimedia interface (HDMI), a universal serial bus (USB) interface, a secure digital (SD) card interface, or an audio interface. The second input module 132 may include a connector capable of being physically connected with the external electronic device ED-A, for example, an HDMI connector, a USB connector, an SD card connector, or an audio connector (e.g., a headphone connector).

The display module 140 may visually provide information to the user. The display module 140 may include the display panel 141, a scan driver 142, and the data driver 143. The display module 140 may further include a window, a chassis, and a bracket for protecting the display panel 141.

The display panel 141 may include a liquid crystal display panel, an organic light emitting display panel, or an inorganic light emitting display panel, and the type of the display panel 141 is not particularly limited. The display panel 141 may be a rigid type, a flexible type that may be rollable or foldable. The display module 140 may further include a supporter, a bracket, or a heat dissipating member that support the display panel 141.

The scan driver 142 may be mounted on the display panel 141 as a driving chip. Furthermore, the scan driver 142 may be integrated on the display panel 141. For example, the scan driver 142 may include an amorphous silicon TFT gate driver circuit (ASG), a low temperature polycrystalline silicon (LTPS) TFT gate driver circuit, or an oxide semiconductor TFT gate driver circuit (OSG) that are internalized in the display panel 141. The scan driver 142 may receive a control signal from the controller 112-1, and output scan signals to the display panel 141 in response to a control signal.

The display panel 141 may further include an emission driver. The emission driver may output an emission control signal to the display panel 141 in response to the control signal received from the controller 112-1. The emission driver may be formed separately from the scan driver 142, or may be integrated into the scan driver 142.

The data driver 143 may receive the control signal from the controller 112-1, convert image data into analog voltages (e.g., data voltages) in response to the control signal, and output data voltages to the display panel 141.

The data driver 143 may be integrated into another component (e.g., the controller 112-1). Functions of the interface conversion circuit and the timing control circuit of the controller 112-1 may be integrated into the data driver 143.

The display module 140 may further include a voltage generating circuit. The voltage generating circuit may output various voltages that are required for driving the display panel 141.

The power module 150 may supply a power to the components of the electronic device ED. The power module 150 may include a battery that stores a power supply voltage. The battery may include a primary cell that is not rechargeable, a secondary cell that is rechargeable, or a fuel cell. The power module 150 may include a power management integrated circuit (PMIC). The PMIC may supply a power optimized for each of the modules described above and below. The power module 150 may include a wireless power transmission/reception member electrically connected with the battery. The wireless power transmission/reception member may include multiple antenna radiators that are in the form of a coil.

The electronic device ED may further include the embedded module 160 and the external module 170. The embedded module 160 may include the sensor module 161, the antenna module 162, and the sound output module 163. The external module 170 may include the camera module 171, a light module 172, and the communication module 173.

The sensor module 161 may sense an input by a user's body or an input by a pen among the first input module 131 and may generate an electrical signal or a data value corresponding to the input. The sensor module 161 may include at least one of a fingerprint sensor 161-1, the input sensor 161-2, and a digitizer 161-3.

The fingerprint sensor 161-1 may generate a data value corresponding to the user's fingerprint. The fingerprint sensor 161-1 may include at least one of an optical fingerprint sensor and a capacitive fingerprint sensor.

The input sensor 161-2 may generate a data value corresponding to coordinate information of the input by the user's body or the input by the pen. The input sensor 161-2 may generate a capacitance change due to the input as a data value. The input sensor 161-2 may sense the input by the passive pen or may exchange data with the active pen.

The input sensor 161-2 may measure a biometric signal such as blood pressure, moisture, or body fat. For example, in case that the user touches his/her body part to a sensor layer or a sensing panel and does not move during a given time period, the input sensor 161-2 may detect the biometric signal based on a change in an electric field caused by the body part and may output the information desired by the user to the display module 140.

The digitizer 161-3 may generate a data value corresponding to the coordinate information of the input by the pen. The digitizer 161-3 may generate the amount of electromagnetic change by the input as a data value. The digitizer 161-3 may sense the input by the passive pen or may exchange data with the active pen.

At least one of the fingerprint sensor 161-1, the input sensor 161-2, and the digitizer 161-3 may be implemented in a sensor layer formed on the display panel 141 through a continuous process. The fingerprint sensor 161-1, the input sensor 161-2, and the digitizer 161-3 may be disposed above or on the display panel 141, and at least one of the fingerprint sensor 161-1, the input sensor 161-2, and the digitizer 161-3, for example, the digitizer 161-3 may be disposed below or under the display panel 141.

At least two or more of the fingerprint sensor 161-1, the input sensor 161-2, and the digitizer 161-3 may be integrally formed as one sensing panel through a same process. In case that at least two or more of the fingerprint sensor 161-1, the input sensor 161-2, and the digitizer 161-3 are integrally formed as one sensing panel, the sensing panel may be disposed between the display panel 141 and the window disposed above or on the display panel 141. According to an embodiment, the sensing panel may be disposed on the window, but the location of the sensing panel is not specifically limited.

At least one of the fingerprint sensor 161-1, the input sensor 161-2, and the digitizer 161-3 may be embedded in the display panel 141. For example, at least one of the fingerprint sensor 161-1, the input sensor 161-2, and the digitizer 161-3 may be simultaneously formed through a process of forming elements (e.g., a light emitting device and transistors) included in the display panel 141.

The sensor module 161 may generate an electrical signal or a data value corresponding to an internal state or an external state of the electronic device ED. The sensor module 161 may further include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 162 may include one or more antennas to transmit or receive a signal or power to or from an external source. According to an embodiment, through an antenna suitable for a communication method, the communication module 173 may transmit a signal to an external electronic device or may receive a signal from the external electronic device. An antenna pattern of the antenna module 162 may be integrated in one component (e.g., the display panel 141) of the display module 140 or the input sensor 161-2.

The sound output module 163 that is a device for outputting a sound signal to the outside of the electronic device ED may include, for example, a speaker used for general purposes such as multimedia playback or recording playback and a receiver used exclusively for receiving calls. According to an embodiment, the receiver and the speaker may be either integrally or separately implemented. A sound output pattern of the sound output module 163 may be integrated in the display module 140.

The camera module 171 may photograph a still image and a moving image. According to an embodiment, the camera module 171 may include one or more lenses, an image sensor, or an image signal processor. The camera module 171 may further include an infrared camera capable of measuring the presence or absence of the user, the location of the user, and the line of sight of the user.

The light module 172 may provide a light. The light module 172 may include a light emitting diode or a xenon lamp. The light module 172 may operate in conjunction with the camera module 171 or may operate independently.

The communication module 173 may establish a wired or wireless communication channel between the electronic device ED and the external electronic device ED-A and may support communication through the established communication channel. The communication module 173 may include at least one of a wireless communication module, such as a cellular communication module, a short-range wireless communication module, or a global navigation satellite system (GNSS) communication module, and a wired communication module, such as a local area network (LAN) communication module or a power line communication module. The communication module 173 may communicate with the external electronic device ED-A over a short-range communication network such as Bluetooth, Wi-Fi direct, or infrared data association (IrDA) or a long-range communication network such as a cellular network, an Internet, or a computer network (e.g., a LAN or WAN). Various kinds of communication modules described above may be implemented in one chip or in separate chips, respectively.

The input module 130, the sensor module 161, the camera module 171, etc. may be used to control the operation of the display module 140 in conjunction with the processor 110.

The processor 110 may output commands or data to the display module 140, the sound output module 163, the camera module 171, or the light module 172 based on the input data received from the input module 130. For example, the processor 110 may generate an image data corresponding to the input data applied through the mouse or the active pen and may output the image data to the display module 140. For example, the processor 110 may generate command data corresponding to the input data and may output the command data to the camera module 171 or the light module 172. In case that input data is not received from the input module 130 during a given time period, the processor 110 may switch an operating mode of the electronic device ED to a low-power mode or a sleep mode such that the power consumption of the electronic device ED is reduced.

The processor 110 may output commands or data to the display module 140, the sound output module 163, the camera module 171, or the light module 172 based on the sensing data received from the sensor module 161. For example, the processor 110 may compare authentication data obtained through the fingerprint sensor 161-1 with authentication data stored in the memory 120 and may execute an application depending on a comparison result. The processor 110 may execute a command based on the sensing data sensed by the input sensor 161-2 or the digitizer 161-3 or may output image data corresponding to the sensing data to the display module 140. In case that the sensor module 161 includes a temperature sensor, the processor 110 may receive temperature data associated with the measured temperature from the sensor module 161 and may further perform luminance correction on the image data based on the temperature data.

The processor 110 may receive measurement data about the presence or absence of the user, the location of the user, and the line of sight of the user from the camera module 171. The processor 110 may further perform the luminance correction on the image data based on the measurement data. For example, the processor 110 that determines the presence or absence of the user through the input from the camera module 171 may display image data with corrected luminance through the data conversion circuit 112-2 or the gamma correction circuit 112-3.

Some of the above components may be connected with each other through a communication method between peripheral devices, for example, a bus, a general purpose input/output (GPIO), a serial peripheral interface (SPI), a mobile industry processor interface (MIPI), or an ultra path interconnect (UPI) link and may exchange signals (e.g., commands or data). The processor 110 may communicate with the display module 140 through an interface. For example, one of the communication methods described above may be used, but the disclosure is not limited thereto.

The electronic device ED according to various embodiments of the disclosure may be implemented as various types of devices. The electronic device ED may include, for example, at least one of a portable communication device (e.g., a smartphone), a computer device, a portable multimedia device, a portable medical device, a camera, a wearable device, and home appliances. The electronic device ED according to an embodiment of the disclosure is not limited to the above devices.

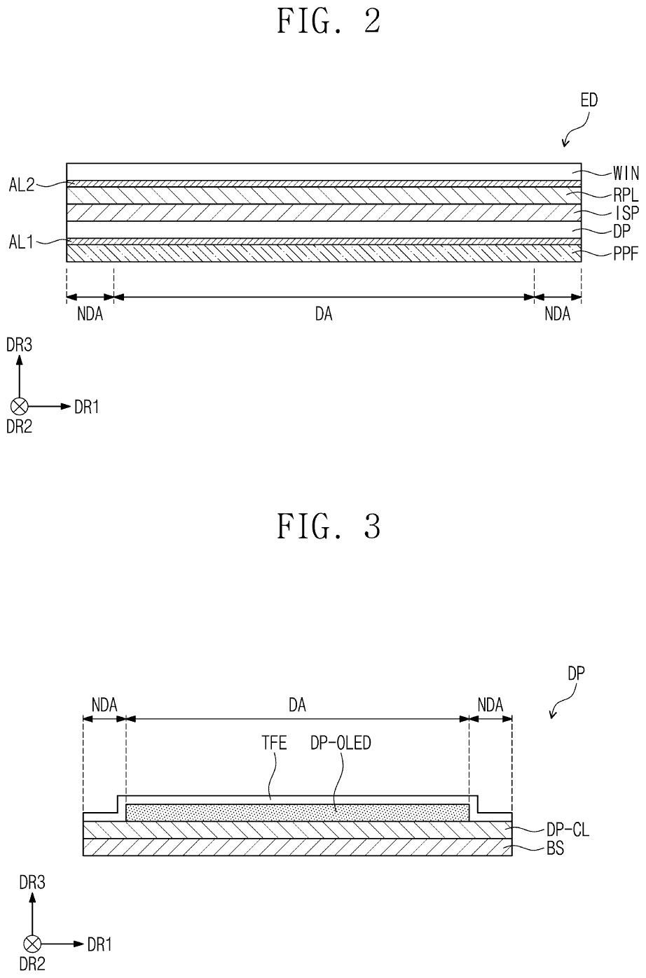

FIG. 2 is a schematic cross-sectional view of the electronic device illustrated in FIG. 1A according to an embodiment. FIG. 3 is a schematic cross-sectional view of a display panel illustrated in FIG. 2 according to an embodiment.

Referring to FIG. 2, an electronic device ED may include a display panel DP, an input sensing part ISP, a reflection prevention layer RPL, a window WIN, a panel protecting film PPF, and first and second adhesion layers AL1 and AL2. The display panel DP may correspond to the above-described display panel 141 (see FIG. 1B), and the input sensing part ISP may correspond to the above-described sensor module 161 (see FIG. 1B).

The display panel DP according to an embodiment of the disclosure may be a light emitting display panel. For example, the display panel DP may be an organic light emitting display panel or an inorganic light emitting display panel. The light emission layer of the organic light emitting display panel may include an organic light emitting material. The light emission layer of the inorganic light emitting display panel may include a quantum dot or a quantum rod. Hereinafter, an embodiment that the display panel DP is an organic light emitting display panel will be described.

Referring to FIG. 3, the display panel DP may include a substrate BS, a circuit element layer DP-CL, a display element layer DP-OLED, and a thin film encapsulation layer TFE. The circuit element layer DP-CL, the display element layer DP-OLED, and the thin film encapsulation layer TFE may be sequentially disposed on the substrate BS.

The substrate BS may include glass or a flexible plastic material such as polyimide (PI).

Multiple pixels may be disposed in the circuit element layer DP-CL and the display element layer DP-OLED. Each of the pixels may include a transistor that is disposed in the circuit element layer DP-CL and a light emitting element that is disposed in the display element layer DP-OLED and connected to the transistor.

The thin film encapsulation layer TFE may be disposed on the circuit element layer DP-CL and cover the display element layer DP-OLED. The thin film encapsulation layer TFE may protect the pixels from moisture, oxygen, and external foreign substances. It is illustrated that the thin film encapsulation layer TFE covers the entire area of the substrate BS, but the disclosure is not limited thereto. In another embodiment of the disclosure, the substrate BS may include a partial area that is exposed from the thin film encapsulation layer TFE, and the area exposed from the thin film encapsulation layer TFE may be formed along a periphery of the substrate BS.

Referring to FIG. 2, the input sensing part ISP may be disposed on the display panel DP. The input sensing part ISP may include multiple sensing parts (not illustrated) for sensing an external input in a capacitive manner. The input sensing part ISP may be formed on (e.g., directly on) the display panel DP when the electronic device ED is manufactured. For example, a conductive pattern or insulating layer that constitutes the input sensing part ISP may be deposited or patterned on (e.g. directly on) the display panel DP. However, the disclosure is not limited thereto, and in another embodiment, the input sensing part ISP may be manufactured as a separate panel from the display panel DP and attached to the display panel DP by an adhesion layer.

Referring to FIG. 2, the reflection prevention layer RPL may be disposed on the input sensing part ISP. The reflection prevention layer RPL may reduce the reflectance of external light of the electronic device ED so that the visibility of an image displayed on the electronic device ED may be improved. The reflection prevention layer RPL may include a phase retarder, a polarizer, a black matrix, a color filter, and the like, but the disclosure is not limited thereto. The reflection prevention layer RPL may be formed on (e.g., directly on) the input sensing part ISP through a coating or deposition process, or may be provided in a film form and attached to the input sensing part ISP by an attachment layer, but the disclosure is not limited thereto.

The window WIN may be disposed on the reflection prevention layer RPL. The window WIN may protect the display panel DP, the input sensing part ISP, and the reflection prevention layer RPL from scratches and external impacts.

The panel protecting film PPF may be disposed under the display panel DP. The panel protecting film PPF may support the display panel DP and protect a lower portion of the display panel DP. The panel protecting film PPF may have insulating properties. For example, the panel protecting film PPF may include a resin such as polyethylene terephthalate (PET), polyimide (PI), polypropylene (PPP), and the like, but the disclosure is not limited thereto.

A first adhesion layer AL1 may be disposed between the display panel DP and the panel protecting film PPF, and the display panel DP and the panel protecting film PPF may be combined with each other by the first adhesion layer AL1. A second adhesion layer AL2 may be disposed between the window WIN and the reflection prevention layer RPL, and the window WIN and the reflection prevention layer RPL may be combined with each other by the second adhesion layer AL2.

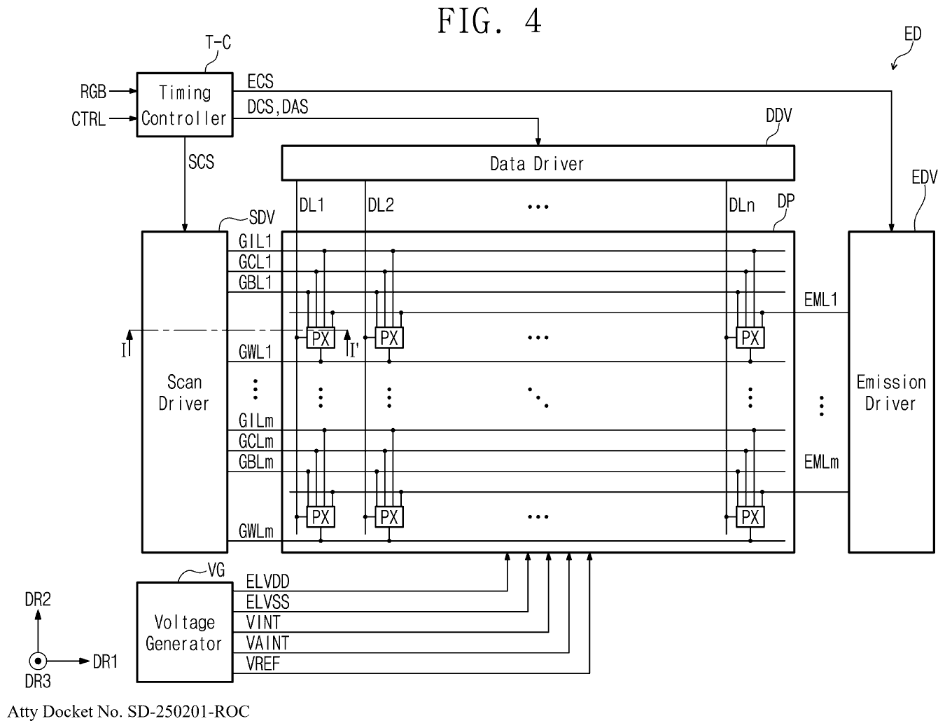

FIG. 4 is a schematic block diagram of the electronic device illustrated in FIG. 1.

Referring to FIG. 4, an electronic device ED may include a display panel DP, a timing controller T-C, a scan driver SDV, a data driver DDV, an emission driver EDV, and a voltage generator VG. The display panel DP, the timing controller T-C, the scan driver SDV, the data driver DDV, the emission driver EDV, and the voltage generator VG may correspond to the display panel 141 (see FIG. 1B), the processor 110 (see FIG. 1B), the scan driver 142 (see FIG. 1B), the data driver 143 (see FIG. 1B), the emission driver (not illustrated), and the power module 150 (see FIG. 1B) described above, respectively.

The display panel DP may include multiple gate lines GIL1 to GILm, GCL1 to GCLm, GWL1 to GWLm, and GBL1 to GBLm, multiple light emission lines EML1 to EMLm, multiple data lines DL1 to DLn, and multiple pixels PX. “m” and “n” may be natural numbers.

The pixels PX may be electrically connected to the gate lines GIL1 to GCLm, GCL1 to GCLm, GWL1 to GWLm, and GBL1 to GBLm, the light emission lines EML1 to EMLm, and the data lines DL1 to DLn, respectively. Each of the pixels PX may be electrically connected to four corresponding gate lines, one corresponding data line, and one corresponding light emission line.

The gate lines GIL1 to GILm, GCL1 to GCLm, GWL1 to GWLm, and GBL1 to GBLm may include multiple initialization gate lines GIL1 to GILm, multiple compensation gate lines GCL1 to GCLm, multiple write gate lines GWL1 to GWLm, and multiple bias gate lines GBL1 to GBLm.

Each of the pixels PX may be connected to a corresponding one of the initialization gate lines GIL1 to GILm, a corresponding one of the compensation gate lines GCL1 to GCLm, a corresponding one of the write gate lines GWL1 to GWLm, and a corresponding one of the bias gate lines GBL1 to GBLm.

The gate lines GIL1 to GILm, GCL1 to GCLm, GWL1 to GWLm, and GBL1 to GBLm may be connected to the scan driver SDV, extend in the first direction DR1, and may be arranged in the second direction DR2. The light emission lines EML1 to EMLm may be connected to the emission driver EDV, extend in the first direction DR1, and may be arranged in the second direction DR2. In an embodiment, the scan driver SDV and the emission driver EDV may be spaced apart from each other with the pixels PX interposed between the scan driver SDV and the emission driver EDV. However, the disclosure is not limited thereto, and in another embodiment, the scan driver SDV and the emission driver EDV may be disposed on a same side with respect to the pixels PX, or may be integrally formed to form one driving part. In another embodiment, each of the scan driver SDV and the emission driver EDV may include multiple divided driving parts.

In an embodiment of the disclosure, the scan driver SDV may be formed and provided on the display panel DP. For example, the scan driver SDV and the pixels PX may be disposed on a same substrate and provided to one display panel DP.

The data lines DL1 to DLn may be connected to the data driver DDV, may extend in the second direction DR2, and may be arranged in the first direction DR1. In an embodiment, the emission driver EDV and the data driver DDV may be substantially disposed on the display panel DP. However, the disclosure is not limited thereto, and in another embodiment, at least one of the emission driver EDV and the data driver DDV may be provided on a separate circuit board to be electrically connected to the display panel DP, so that an electrical signal may be provided to the pixels PX.

The timing controller T-C may receive an image signal RGB and a control signal CTRL. A timing controller T-C may generate an image data signal DAS obtained by converting the data format of the image signal RGB to meet the interface specification with the data driver DDV. The timing controller T-C may output a gate control signal SCS, a data control signal DCS, and an emission control signal ECS in response to a control signal CTRL.

The voltage generator VG may generate voltages required to operate the display panel DP. The voltage generator VG may generate a first driving voltage ELVDD, a second driving voltage ELVSS, a first initialization voltage VINT, and a reference voltage VREF. The first driving voltage ELVDD, the second driving voltage ELVSS, the first initialization voltage VINT, the second initialization voltage VAINT, and the reference voltage VREF may be applied to the pixels PX.

The scan driver SDV may receive a gate control signal SCS from the timing controller T-C. The scan driver SDV may output gate signals to the gate lines GIL1 to GILm, GCL1 to GCLm, GWL1 to GWLm, and GBL1 to GBLm in response to the gate control signal SCS. The gate signals may be applied to the pixels PX through the gate lines GIL1 to GCLm, GCL1 to GCLm, GWL1 to GWLm, and GBL1 to GBLm.

The data driver DDV may receive a data control signal DCS and an image data signal DAS from the timing controller T-C. The data driver DDV may convert the image data signal DAS into data signals and output the converted data signal. The data signals may be analog voltages corresponding to the gray level of the image data signal DAS. The data signals may be applied to the pixels PX through the data lines DL1 to DLn.

The emission driver EDV may receive an emission control signal ECS from the timing controller T-C. The emission driver EDV may output light emission signals to the light emission lines EML1 to EMLm in response to the emission control signal ECS. The light emission signals may be applied to the pixels PX through the light emission lines EML1 to EMLm.

The pixels PX may receive data voltages in response to gate signals. The pixels PX may display an image by emitting light having a luminance corresponding to data voltages in response to light emission signals.

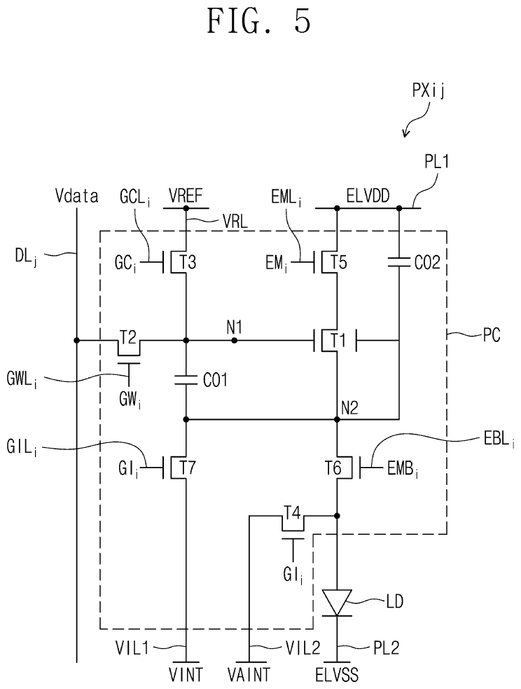

FIG. 5 is a schematic diagram of an equivalent circuit of one of pixels according to an embodiment of the disclosure. FIG. 5 schematically illustrates a pixel PXij that are connected to i-th gate lines GILi, GCLi, GWLi, and EBLi, a j-th data line DLj, and an i-th light emission line EMLi. “i” and “j” may be natural numbers.

Referring to FIG. 5, a pixel PXij may include a light emitting element LD and a pixel driver PC.

The light emitting element LD may be electrically connected to a power line and a pixel driver PC.

The pixel driver PC may drive the light emitting element LD. The pixel driver PC may include multiple transistors T1 to T7 and capacitors C01 and C02. The transistors T1 to T7 and the capacitors C01 and C02 may control an amount of current that flows in the light emitting element LD. The light emitting element LD may generate light having a luminance depending on the amount of the provided current.

The pixel PXij may be connected to the j-th data line DLj. Furthermore, the pixel PXij may be connected to power lines connected to the voltage generator VG (see FIG. 4), and receive a first initialization voltage VINT, a second initialization voltage VAINT, a reference voltage VREF, a first driving voltage ELVDD, and a second driving voltage ELVSS, respectively.

FIG. 5 schematically illustrates signals that are transmitted to the pixel PXij. An i-th write gate line GWLi may receive an i-th write gate signal GWi, and an i-th compensation gate line GCLi may receive an i-th compensation gate signal GCi. An i-th initialization gate line GILi may receive an i-th initialization gate signal GIi.

An i-th light emission line EMLi may receive an i-th light emission signal EMi, and an i-th bias light emission line EBLi may receive an i-th bias light emission signal EMBi. A j-th data line DLj may receive data voltage Vdata. The first initialization line VIL1 may receive a first initialization voltage VINT, and the second initialization line VIL2 may receive a second initialization voltage VAINT. The reference line VRL may receive a reference voltage VREF. The first power line PL1 may receive a first driving voltage ELVDD, and the second power line PL2 may receive a second driving voltage ELVSS.

The pixel driver PC may include first to seventh transistors T1, T2, T3, T4, T5, T6, and T7, a first capacitor C01, and a second capacitor C02. Each of the transistors T1 to T7 may include a source electrode, a drain electrode, and a gate electrode. Hereinafter, in FIG. 5, for convenience, one of the source electrode and the drain electrode may be described as a first electrode, and another one of the source electrode and the drain electrode may be described as a second electrode.

The transistors T1 to T7 may include first to seventh transistors T1 to T7. In an embodiment, each of the first to seventh transistors T1 to T7 may be a transistor including an oxide semiconductor. Each of the first to seventh transistors T1 to T7 may be a P-type or an N-type.

The first transistor T1 may be connected between the emission control transistors T5 and T6 that will be described below. A gate of the first transistor T1 may be connected to a first node N1. A first electrode of the first transistor T1 may be connected to the fifth transistor T5, and a second electrode thereof may be connected to a second node N2. The second electrode of the first transistor T1 may be connected to the sixth transistor T6, the seventh transistor T7, the first capacitor C01, and the second capacitor C02 through the second node N2. The first transistor T1 may be a driving transistor. The first transistor T1 may control a driving current that flows in the light emitting element LD corresponding to a voltage of the first node N1. The first driving voltage ELVDD may be set as a voltage having a higher potential than the second driving voltage ELVSS.

In an embodiment, the first transistor T1 may further include a bottom gate. For example, the first transistor T1 may have a dual gate structure. The bottom gate may be connected to the second node N2, and the second node N2 may be connected to the second electrode of the first transistor T1. For example, the bottom gate of the first transistor T1 may form a source-sync structure. The first transistor T1 according to an embodiment may have a source synchronization structure, so that a channel area, in which a driving range is secured may be formed.

The second transistor T2 may be disposed between the first transistor T1 and a j-th data line DLj and connected to the first transistor T1 and the j-th data line DLj. The second transistor T2 may include a gate that is connected to the write scan line GWLi, a first electrode that is connected to the data line DLj, and a second electrode that is connected to the first node N1. The second transistor T2 may supply the data voltage Vdata to the first node N1 in response to the i-th write gate signal GWi transmitted through the write scan line GWLi. The second transistor T2 may be turned on in case that the i-th write gate signal GWi is received to electrically connect the data line DLj to the first node N1.

The third transistor T3 may be connected between the first node N1 and a voltage line receiving the reference voltage VREF. A first electrode of the third transistor T3 may receive the reference voltage VREF, and a second electrode of the third transistor T3 may be connected to the first node N1. In an embodiment, a gate of the third transistor T3 may receive the i-th compensation gate signal GCi. The third transistor T3 may be turned on in case that the compensation gate signal GCi is supplied to the gate to provide the reference voltage VREF to the first node N1.

The fourth transistor T4 may be connected between the light emitting element LD and a power line that receives the second initialization voltage VAINT. A first electrode of the fourth transistor T4 may be connected to the anode of the light emitting element LD and the sixth transistor T6, and a second electrode of the fourth transistor T4 may receive the second initialization voltage VAINT. The fourth transistor T4 may be referred to as a first initialization transistor. A gate of the fourth transistor T4 may receive the i-th initialization gate signal GIi. The fourth transistor T4 may be turned on in case that the first initialization scan signal GIi is supplied to the gate to provide the second initialization voltage VAINT to the anode of the light emitting element LD.

The fifth transistor T5 may be connected between a power line that receives the first driving voltage ELVDD and the first transistor T1. A first electrode of the seventh transistor T7 may receive the first driving voltage ELVDD, and a second electrode of the seventh transistor T7 may be connected to the first electrode of the first transistor T1. A gate of the seventh transistor T7 may receive an i-th light emission signal EMi. The fifth transistor T5 may be referred to as a first emission control transistor. In case that the i-th light emission signal EMi is supplied, the fifth transistor T5 may be turned on to electrically connect the first electrode of the first transistor T1 and a power line that receives the first driving voltage ELVDD.

The sixth transistor T6 may be connected between the first transistor T1 and the light emitting element LD. For example, the first electrode of the sixth transistor T6 may be connected to the second node N2 and the second electrode may be connected to the anode of the light emitting element LD. A first electrode of the sixth transistor T6 may be connected to the second electrode of the first transistor T1, the first capacitor C01, the seventh transistor T7, and the second capacitor C02 through the second node N2. A gate of the sixth transistor T6 may receive an i-th bias light emission signal EMBi. The sixth transistor T6 may be referred to as a second emission control transistor. In case that the i-th light emission signal EMBi is supplied, the sixth transistor T6 may be turned on to electrically connect the light emitting element LD and the first transistor T1.

It is illustrated that the fifth transistor T5 and the sixth transistor T6 are independently turned on by different light emission signals EMi and EMBi, but the disclosure is not limited thereto, and in another embodiment, the fifth transistor T5 and the sixth transistor T6 may be turned on by a same signal. Furthermore, in the pixel driver PC according to an embodiment of the disclosure, one of the fifth transistor T5 and the sixth transistor T6 may be omitted.

The seventh transistor T7 may be connected between the second node N2 and a power line that receives the first initialization voltage VINT. A first electrode of the seventh transistor T7 may be connected to the first capacitor C01, the first transistor T1, the sixth transistor T6, and the second capacitor C02 through the second node N2, respectively. A second electrode of the seventh transistor T7 may receive the first initialization voltage VINT. The seventh transistor T7 may be referred to as a second initialization transistor. A gate of the seventh transistor T7 may receive the i-th initialization gate signal GIi. The seventh transistor T7 may be turned on in case that the i-th initialization gate signal GIi is supplied to the gate to provide the first initialization voltage VINT to an electrode of the first capacitor C01 and the second electrode of the first transistor T1.

It is illustrated that the fourth transistor T4 and the seventh transistor T7 are turned on by a same i-th initialization gate signal GIi, but the disclosure is not limited thereto, and in another embodiment, the fourth transistor T4 and the seventh transistor T7 may be turned on independently by different scan signals.

The first capacitor C01 may be disposed between the first node N1 and the second node N2. The first capacitor C01 may store a differential voltage between the first node N1 and the second node N2. The first capacitor C01 may be referred to as a storage capacitor.

The second capacitor C02 may be disposed between the second node N2 and a power line that receives the first driving voltage ELVDD. For example, one electrode of the second capacitor C02 may receive the first driving voltage ELVDD, and another one electrode of the second capacitor C02 may be connected to the first transistor T1, the sixth transistor T6, the seventh transistor T7, and the first capacitor C01 through the second node N2. The second capacitor C02 may store a charge corresponding to a voltage difference between the first driving voltage ELVDD and the second node N2. The second capacitor C02 may be referred to as a hold capacitor. The second capacitor C02 may have a higher storage capacity than the first capacitor C01.

The number or the connection relationship of transistors that constitute the pixel driver PC may be variously changed, and the number or the connection relationship of the capacitors is not limited to any one embodiment.

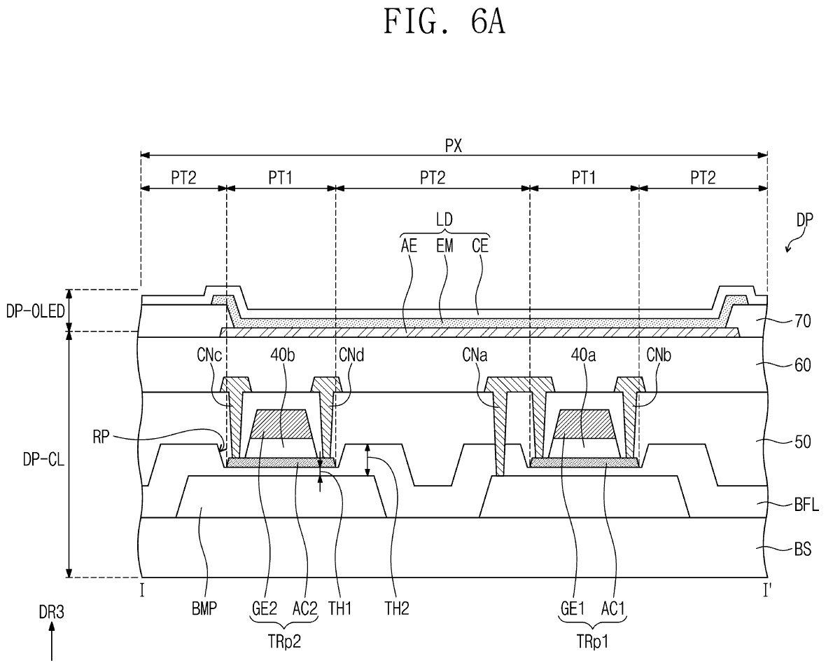

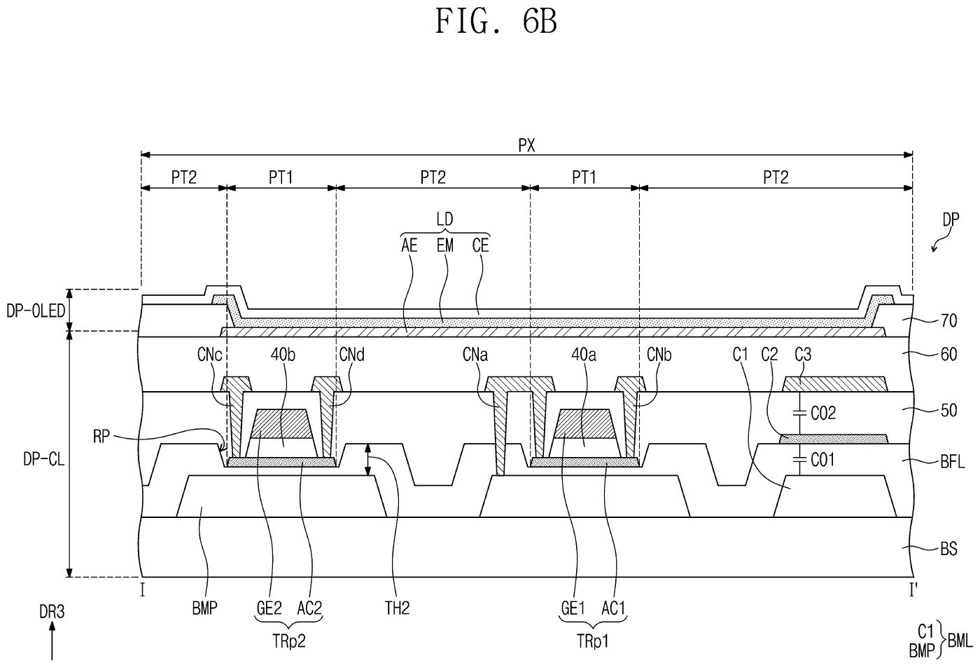

FIGS. 6A and 6B are schematic cross-sectional views of a display panel according to an embodiment of the disclosure. FIGS. 6A and 6B schematically illustrate a cross section taken along line I-I′ illustrated in FIG. 4.

Referring to FIG. 6A, the display panel DP may include a circuit element layer DP-CL and a display element layer DP-OLED.

The circuit element layer DP-CL may include driving elements, a substrate BS, a lower conductive layer BML, a buffer layer BFL, and insulating layers 50 and 60. The buffer layer BFL may include first to third insulating layers 10, 20, and 30.

Referring to FIG. 6A, the driving elements may include two transistors TRp1 and TRp2 (hereinafter referred to as pixel transistors) and two capacitors C01 and C02, among the transistors that constitute the pixel driver PC (see FIG. 5).

The substrate BS may include a glass substrate, a sapphire substrate, a plastic film, or an organic/inorganic laminated film. The substrate BS may have a multi-layered or single-layered structure. For example, the substrate BS may have a laminated structure of multiple plastic films coupled to each other by an adhesive, or may have a laminated structure of a glass substrate and a plastic film coupled to each other by an adhesive. The substrate BS may have flexibility. For example, the substrate BS may include polyimide (PI). However, the disclosure is not limited thereto, and in another embodiment, the substrate BS may be provided in a rigid state.

The lower conductive layer BML may include multiple lower conductive patterns BMP. Lower conductive patterns BMP may be disposed on the substrate BS. The lower conductive patterns BMP may constitute a pixel PX. The lower conductive patterns BMP may include a conductive material, for example, a metal. In an embodiment, the lower conductive patterns BMP may include a light shielding material. The lower conductive patterns BMP may include a same material, but the disclosure is not limited thereto, and in another embodiment, the lower conductive patterns BMP may include different materials. The lower conductive patterns BMP may overlap the transistor and the like in a plan view to protect the semiconductor pattern and the like of the transistor. The lower conductive patterns BMP may be disposed under the transistor to block electrical potentials from affecting the transistor or to block external light from reaching the transistor.

One of the lower conductive patterns BMP may be connected to the first semiconductor pattern AC1. One of the lower conductive patterns BMP may function as a bottom gate of the first transistor TRp1 and may be connected to the first transistor TRp1. Another one of the lower conductive patterns BMP may be an electrode of the first capacitor C01. The lower conductive layer BML may further include a lower conductive pattern BMP that overlaps the second semiconductor pattern AC2 in a plan view and is insulated from the second semiconductor pattern AC2.

The insulating layers 10, 20, 30, 40, 50, and 60 may include first to sixth insulating layers 10, 20, 30, 40, 50, and 60 that are sequentially stacked on the substrate BS, but the disclosure is not limited thereto, and the number of the insulating layers that constitute the circuit element layer DP-CL may be variously changed.

The buffer layer BFL may be disposed on the substrate BS to cover the lower conductive patterns BMP. The buffer layer BFL may improve a coupling strength between the semiconductor patterns AC1 and AC2 and the lower conductive patterns BMP. The buffer layer BFL may include an insulating material. For example, the buffer layer BFL may include at least one of aluminum oxide, titanium oxide, silicon nitride, silicon nitride, silicon oxy nitride, zirconium oxide, and hafnium oxide, but the disclosure is not limited thereto.

The buffer layer BFL may include a first part PT1 (or the first area) and a second part PT2 (or the second area) having different thicknesses. The first part PT1 may have a first thickness TH1. The second part PT2 may have a second thickness TH2. The first thickness TH1 may be smaller than the second thickness TH2.

The first part PT1 may overlap at least portions of the lower conductive patterns BMP. For example, the first part PT1 may be disposed on one of the lower conductive patterns BMP. Multiple first parts PT1 may be provided, and may be disposed on the lower conductive patterns BMP, respectively.

The second part PT2 may overlap areas between the lower conductive patterns BMP in a plan view. The second part PT2 may be connected to the first part PT1 to form a buffer layer BFL having an integral shape. Accordingly, the first part PT1 may be a recessed part RP having a shape that is recessed from the second part PT2.

The transistors TRp1 and TRp2 may be disposed on the buffer layer BFL. It is illustrated that the transistors TRp1 and TRp2 are the first transistor T1 (see FIG. 5) illustrated in FIG. 5 according to an embodiment. However, the disclosure is not limited thereto, and in another embodiment the transistors TRp1 and TRp2 may correspond to the second to seventh transistors T2 to T7 illustrated in FIG. 5.

The first transistor TRp1 may include a gate GE1 (hereinafter, referred to as a first gate) and a semiconductor pattern AC1 (hereinafter, referred to as a first semiconductor pattern). The first transistor TRp1 may be disposed in the first part PT1 of the buffer layer BFL. In an embodiment, the first semiconductor pattern AC1 may be disposed in the recessed part RP.

The second transistor TRp2 may be disposed on the buffer layer BFL. The second transistor TRp2 and the first transistor TRp1 may be disposed on a same layer. The second transistor TRp2 may include a gate GE2 (hereinafter, referred to as a second gate) and a semiconductor pattern AC2 (hereinafter, referred to as a second semiconductor pattern). The second transistor TRp2 may be disposed on the first part PT1 of the buffer layer BFL.

Each of the first semiconductor pattern AC1 and the second semiconductor pattern AC2 may be disposed in the first part PT1. For example, each of the first semiconductor pattern AC1 and the second semiconductor pattern AC2 may be disposed in the recessed part RP and may overlap a corresponding lower conductive pattern BMP in a plan view.

The first semiconductor pattern AC1 may include an oxide semiconductor. For example, the first semiconductor pattern AC1 may include at least one of indium, gallium, and zinc. In an embodiment, the first semiconductor pattern AC1 may include a transparent conductive oxide (TCO) such as indium-tin oxide (ITO), indium-gallium-zinc oxide (IGZO), zinc oxide (ZnO), zinc-indium oxide (ZIO), indium oxide (InO), titanium oxide (TiO), indium-zinc-tin oxide (IZTO), zinc-tin oxide (ZTO), and the like, as an oxide semiconductor material.

The first semiconductor pattern AC1 may be divided into a source area, a drain area, and a channel area depending on conductivity. For example, the channel area may be an area having a relatively low conductivity compared to the source area and the drain area, and may overlap the first gate GE1 in a plan view.

The source area and the drain area may be areas that are spaced apart from each other with a channel area interposed between the source area and the drain area, and each may be an area having conductivity. Each of the source area and the drain area may be formed through doping or reduction. For example, in an oxide semiconductor pattern, the reduced area may have a higher conductivity than other area. Because the metal oxide that constitutes the oxide semiconductor pattern is deposited as a metal through a reduction process, the area, in which the metal oxide is reduced, may be a source area and a drain area, and the remaining area may be a channel area.

The second semiconductor pattern AC2 may be disposed on the buffer layer BFL. The second semiconductor pattern AC2 and the first semiconductor pattern AC1 may be disposed on a same layer. The second semiconductor pattern AC2 may be spaced apart from the first semiconductor pattern AC1. In an embodiment, the second semiconductor pattern AC2 may be disposed on the exposed first insulating layer 10 by removing the first insulating layer 10 (or a lower oxide layer) and the second insulating layer 20 (or a nitride layer).

The second semiconductor pattern AC2 may include an oxide semiconductor. For example, the second semiconductor pattern AC2 may include a transparent conductive oxide (TCO) such as indium-tin oxide (ITO), indium-gallium-zinc oxide (IGZO), zinc oxide (ZnO), zinc-indium oxide (ZIO), indium oxide (InO), titanium oxide (TiO), indium-zinc-tin oxide (IZTO), zinc-tin oxide (ZTO), and the like, as an oxide semiconductor material.

Like the first semiconductor pattern AC1, the second semiconductor pattern AC2 may be divided into a source area, a drain area, and a channel area depending on conductivity. For example, the channel area may be an area having a relatively low conductivity compared to the source area and the drain area, and may overlap the second gate GE2 in a plan view. The source area and the drain area may be areas that are spaced apart from each other with a channel area interposed between the source area and the drain area, and each may be an area having conductivity. The source area and the drain area may be areas, in which metal oxides are reduced and metal deposits are included.

The fourth insulating layer 40 may be disposed on the buffer layer BFL. The fourth insulating layer 40 may include multiple insulating patterns 40a and 40b. The fourth insulating layer 40 may cover the first and second semiconductor patterns AC1 and AC2. One 40a of the two insulating patterns 40a and 40b may be disposed between the first semiconductor pattern AC1 and the first gate GE1 and may function as a gate insulating film of the first transistor TRp1. Another one 40b of the two insulating patterns 40a and 40b may be disposed between the second semiconductor pattern AC2 and the second gate GE2 and may function as a gate insulating film of the second transistor TRp2.

The fifth insulating layer 50 may be disposed on the third insulating layer 30 (or an upper oxide layer) and cover the insulating patterns 40a and 40b and the first and second gates GE1 and GE2. The fifth insulating layer 50 may include an organic layer or an organic layer and an inorganic layer.

Connection electrodes CNa, CNb, CNc, and CNd may be disposed on the fifth insulating layer 50. The connection electrodes CNa, CNb, CNc, and CNd may pass through the fifth insulating layer 50 to be electrically connected to a source area and a drain area of the first semiconductor pattern AC1 or the second semiconductor pattern AC2, respectively.

One CNa of the connection electrodes CNa, CNb, CNc, and CNd constituting the pixel PX may be connected to one of the lower conductive patterns BMP, the lower conductive patterns BMP may serve as a bottom gate for the first semiconductor pattern AC1, and the first transistor TRp1 may have a dual gate structure including a first gate GE1 and a bottom gate. The first transistor TRp1 may have a source-sync structure, and the first transistor TRp1 illustrated in FIG. 6A may correspond to the first transistor T1 illustrated in FIG. 5. However, the disclosure is not limited thereto, and in another embodiment, the connection electrodes CNa, CNb, CNc, and CNd may not be connected to the lower conductive patterns BMP.

The sixth insulating layer 60 may be disposed on the fifth insulating layer 50. The sixth insulating layer 60 may cover connection electrodes CNa, CNb, CNc, and CNd. The display element layer DP-OLED may be disposed on the sixth insulating layer 60.

The display element layer DP-OLED may include a light emitting element LD and a seventh insulating layer 70. The seventh insulating layer 70 may be disposed on the sixth insulating layer 60. The seventh insulating layer 70 may provide an opening to the pixel PX. The seventh insulating layer 70 may function as a pixel definition film.

The light emitting element LD may include an anode AE, a light emission layer EM, and a cathode CE. The seventh insulating layer 70 may expose at least a portion of the anode AE through an opening. The light emission layer EM may be disposed in the opening, and may be disposed between the anode AE and the cathode CE. The cathode CE may be disposed on the seventh insulating layer 70 and may cover the entire display area.

Referring to FIG. 6A, a thickness TH1 (hereinafter, referred to as a first thickness) of the buffer layer BFL that overlaps the first part PT1 may be different from a thickness of the buffer layer BFL that does not overlap the first part PT1 in a plan view. The first thickness TH1 may be smaller than a thickness of the buffer layer BFL that does not overlap the first part PT1 in a plan view. For example, a thickness of the first part PT1, in which the transistors TRp1 and TRp2 are disposed, may be smaller than a thickness of a portion, at which the transistors TRp1 and TRp2 are not disposed.

In case that the thickness of the buffer layer BFL that overlaps the transistors TRp1 and TRp2 is formed to be thin, a tendency of the threshold voltage to move in a negative direction may be reduced. For example, as the thickness of the buffer layer BFL becomes thinner, a degree of movement of the threshold voltage Vth of the first semiconductor pattern AC1 and the second semiconductor pattern AC2 in the negative direction may be relatively low. However, in case that the thickness of the buffer layer BFL is formed to be thin as a whole, a step coverage issue may occur. For example, in case that the buffer layer BFL is formed to be thin as a whole, it may be difficult to uniformly and continuously cover the upper and side surfaces of the lower conductive patterns BMP having a relatively large thickness. In case that only a portion of the buffer layer BFL, which overlaps the transistors TRp1 and TRp2 in a plan view, is formed to be thin, a step coverage issue may not occur and a tendency of the threshold voltage to move in the negative direction may be reduced.

Furthermore, as the thickness of the buffer layer BFL that overlaps the transistors TRp1 and TRp2 becomes thinner, a parasitic capacitance (hereinafter, referred to as a capacitance) that is formed by the lower conductive patterns BMP and the semiconductor patterns AC1 and AC2 may increase. In case that the capacitance increases, a force that prevents electrons from being collected in the channel area may increase. Accordingly, a driving range of the gate voltage that is applied to the driving gate electrode may increase. In case that the driving range of the gate voltage increases, the grayscale of light that is emitted from the light emitting element LD may be more precisely controlled by changing the magnitude of the gate voltage, and as a result, a resolution of the electronic device ED may be increased and a display quality thereof may be improved.

Referring to FIG. 6B, the display panel may further include a capacitor. The capacitor may include a first electrode C1, a second electrode C2, and a third electrode C3. The capacitor may be disposed in an area of the second part PT2, which overlaps the lower conductive pattern BMP in a plan view.

The first electrode C1 may be disposed between the substrate BS and the buffer layer BFL. The first electrode C1 may be one of the lower conductive patterns BMP that constitute the lower conductive layer BML.

The second electrode C2 may be disposed between the buffer layer BFL and the fifth insulating layer 50. The second electrode C2 and the first and second semiconductor patterns AC1 and AC2 may be disposed on a same layer. In an embodiment, the second electrode C2 and the first and second semiconductor patterns AC1 and AC2 may be formed of a same semiconductor material. However, the disclosure is not limited thereto, and in another embodiment, the second electrode C2 and the first and second semiconductor patterns AC1 and AC2 may be formed of different conductive materials. The second electrode C2 and the first electrode C1 may form the first capacitor C01.

The third electrode C3 may be disposed between the fifth insulating layer 50 and the sixth insulating layer 60. The third electrode C3 and the connection electrodes CNa, CNb, CNc, and CNd may be disposed on a same layer. In an embodiment, the third electrode C3 and the connection electrodes CNa, CNb, CNc, and CNd may be formed of a same semiconductor material. For example, the third electrode C3 may include an oxide semiconductor. For example, the third electrode C3 may include a transparent conductive oxide (TCO), such as indium-tin oxide (ITO), indium-gallium-zinc oxide (IGZO), zinc oxide (ZnO), indium-zinc oxide (IZnO), zinc-indium oxide (ZIO), indium oxide (InO), titanium oxide (TiO), indium-zinc-tin oxide (IZTO), zinc-tin oxide (ZTO), and the like, and an oxide semiconductor material.

However, the disclosure is not limited thereto, and the third electrode C3 the connection electrodes CNa, CNb, CNc, and CNd may be formed of different conductive materials. The third electrode C3 and the second electrode C2 may form the second capacitor C02.

The buffer layer BFL disposed between the first electrode C1 and the second electrode C2 may insulate the first electrode C1 and the second electrode C2 from each other, and may function as a dielectric of the first capacitor C01 between the first electrode C1 and the second electrode C2. The fifth insulating layer 50 disposed between the second electrode C2 and the third electrode C3 may insulate the second electrode C2 and the third electrode C3 from each other, and may function as a dielectric of the second capacitor C02 between the second electrode C2 and the third electrode C3.

Because the second part PT2 has the second thickness TH2 that is greater than the first thickness TH1, the capacitors C01 and C02 disposed in the second part PT2 may have a sufficient capacitance. According to the disclosure, because the first part PT1 of the buffer layer BFL, which has a relatively small thickness, is disposed in an area, in which the semiconductor patterns AC1 and AC2 are disposed, a phenomenon, in which a threshold voltages of the transistors TRp1 and TRp2 is moved in a negative direction, may be prevented even in case that the semiconductor patterns AC1 and AC2 provide a short channel length, and the driving voltage ranges of the transistors TRp1 and TRp2 may be increased. Furthermore, according to the disclosure, because the second part PT2 of the buffer layer BFL, which has a relatively large thickness, is disposed in an area other than an area, in which the semiconductor patterns AC1 and AC2 constitute the transistor, are disposed, the lower conductive patterns BMP may be sufficiently covered by the buffer layer BFL. Accordingly, it may be possible to prevent a step coverage issue from occurring due to the thickness of the lower conductive patterns BMP. Furthermore, because the second part PT2 is also disposed in the area, in which the capacitors C01 and C02 are formed, a sufficient capacity for the capacitors C01 and C02 may be secured. According to the disclosure, by selectively designing the thickness of the buffer layer BFL differently depending on the area, in which the elements are disposed, a display panel with an improved reliability may be provided by improving electronic characteristics required for each element.

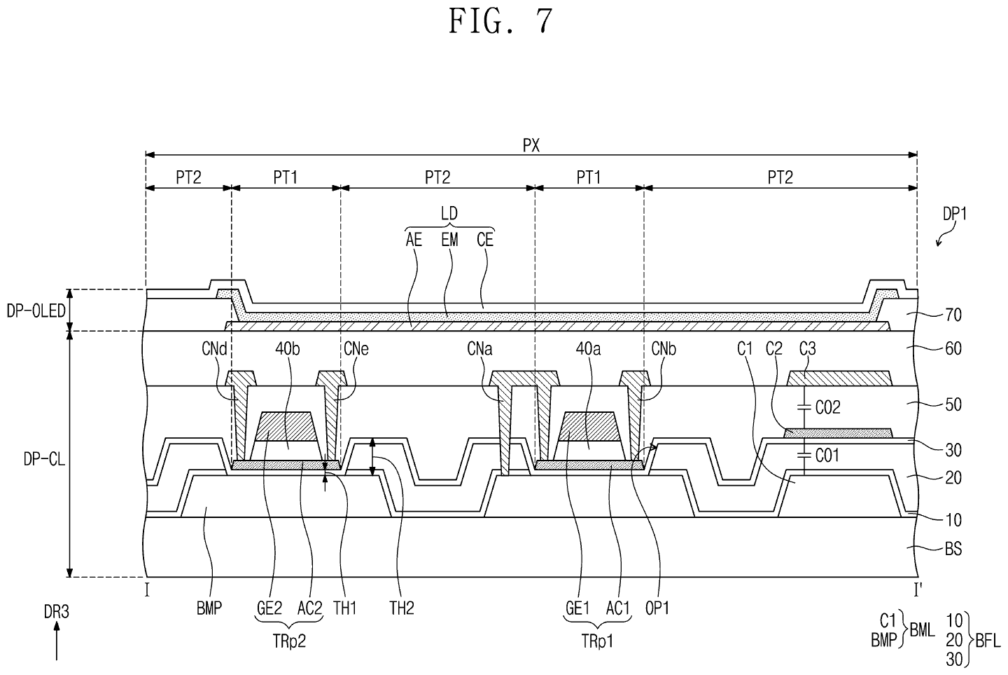

FIG. 7 is a schematic cross-sectional view of a display panel DP1 according to an embodiment of the disclosure. Hereinafter, in a description with reference to FIG. 7, the same/similar reference numerals are used for configurations which are the same as/similar to those described in FIGS. 6A and 6B, and a repeated description thereof will be omitted.

Referring to FIG. 7, the buffer layer BFL may include multiple layers. For example, the buffer layer BFL may include first to third insulating layers 10, 20, and 30.

The first insulating layer 10 (or a lower oxide layer) may be an oxide layer. The first insulating layer 10 may include silicon oxide. For example, the first insulating layer 10 may include silicon oxide (SiO₂).

The second insulating layer 20 (or a nitride layer) may be disposed on the first insulating layer 10. The second insulating layer 20 may be a nitride layer. The second insulating layer 20 may include silicon nitride. The second insulating layer 20 may be formed of a material having a chemical formula of SiNₓ.

The third insulating layer 30 (or an upper oxide layer) may be disposed on the second insulating layer 20. The third insulating layer 30 may be an oxide layer. The third insulating layer 30 may include silicon oxide. For example, the third insulating layer 30 may be formed of a material having a chemical formula of SiOₓ. For example, the third insulating layer 30 may include silicon oxide (SiO₂). In an embodiment, the third insulating layer 30 and the first insulating layer 10 may be formed of a same material. However, the disclosure is not limited thereto, and in another embodiment, the third insulating layer 30 and the first insulating layer 10 may be formed of different materials.

As illustrated in FIG. 7, an opening OP1 that passes through the first insulating layer 10 and the second insulating layer 20 may be defined in the buffer layer BFL. The first part PT1 may include a single layer including the first insulating layer 10, and the second part PT2 may include multiple layers, in which the first to third insulating layers 10, 20, and 30 are laminated. However, the disclosure is not limited thereto, and the buffer layer BFL may have various structures as long as the first part PT1 and the second part PT2 having different thicknesses may be included.

The first semiconductor pattern AC1 and the second semiconductor pattern AC2 may be disposed in the first part PT1. The first semiconductor pattern AC1 and the second semiconductor pattern AC2 may be disposed in the opening OP1 and contact the third insulating layer 30.

Referring to FIG. 7, the first thickness TH1 may be a thickness of the third insulating layer 30. The second thickness TH2 may be a value obtained by adding all the thicknesses of the first to third insulating layers 10, 20, and 30.

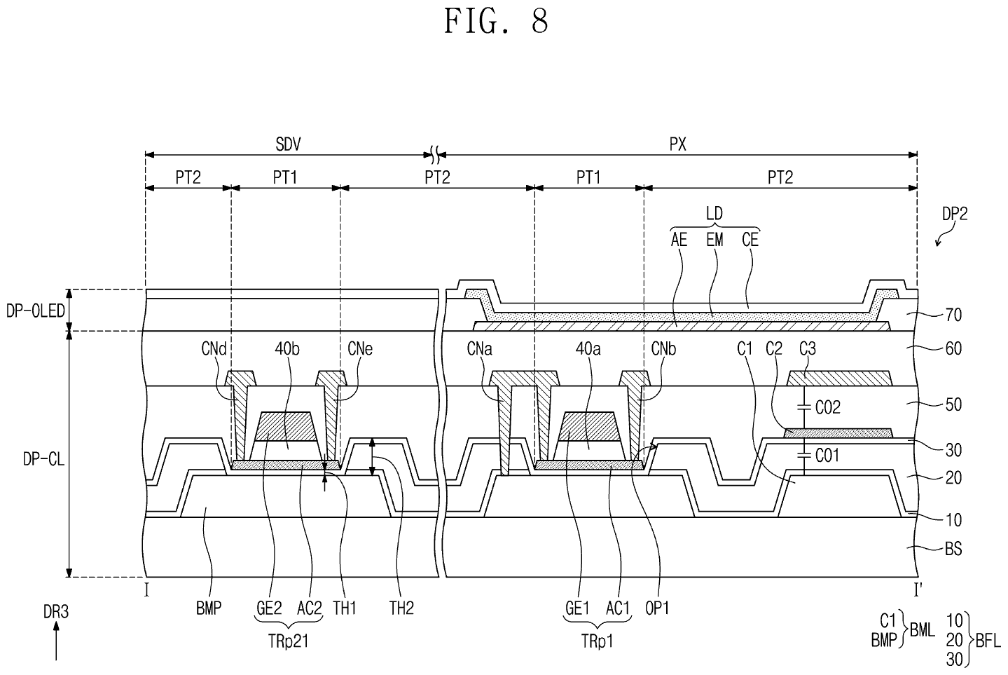

FIG. 8 is a schematic cross-sectional view of a display panel according to an embodiment of the disclosure. FIG. 8 schematically illustrates a cross section taken along line I-I′ of FIG. 4, and an embodiment, in which the scan driver SDV is mounted on the display panel DP2, is illustrated. Hereinafter, in a description with reference to FIG. 8, the same/similar reference numerals are used for the same/similar configurations as those described in FIGS. 6A to 7, and a repeated description thereof are omitted.

Referring to FIG. 8, the driving elements may include, one transistor TRp1 (hereinafter, referred to as a first transistor), among the transistors that constitute the pixel driver PC (see FIG. 5), one capacitor, and one transistor TRp2 (hereinafter, referred to as a second transistor) that constitutes the scan driver SDV (see FIG. 4). Unlike in FIG. 6, the second transistor TRp21 may be one of transistors that constitute the scan driver SDV.

One 40b of the insulating patterns 40a, 40b, and 40c may be disposed on the scan driver SDV. Among the connection electrodes CNa, CNb, CNc, and CNd and the third electrode C3, the electrodes CNa, CNb, and C3 that constitute the pixel PX may pass through the fifth insulating layer 50 to be electrically connected to a source area and a drain area of the first semiconductor pattern AC1 or the second electrode C2, respectively. Among the connection electrodes CNa, CNb, CNc, and CNd and the third electrode C3, the electrode patterns CNc and CNd that constitute the scan driver SDV may pass through the fifth insulating layer 50 to be electrically connected to a source area and a drain area of the second semiconductor pattern AC2, respectively.

According to the disclosure, by providing the first part PT1 of the buffer layer BFL to the second transistor TRp21 that constitutes the scan driver SDV, a phenomenon, in which a threshold voltage of the transistor TRp21 having a short channel length is moved in a negative direction, may be reduced. Accordingly, a sufficient threshold voltage may be secured in the second transistor TRp21 that constitutes the scan driver SDV, and on/off characteristics may be improved.

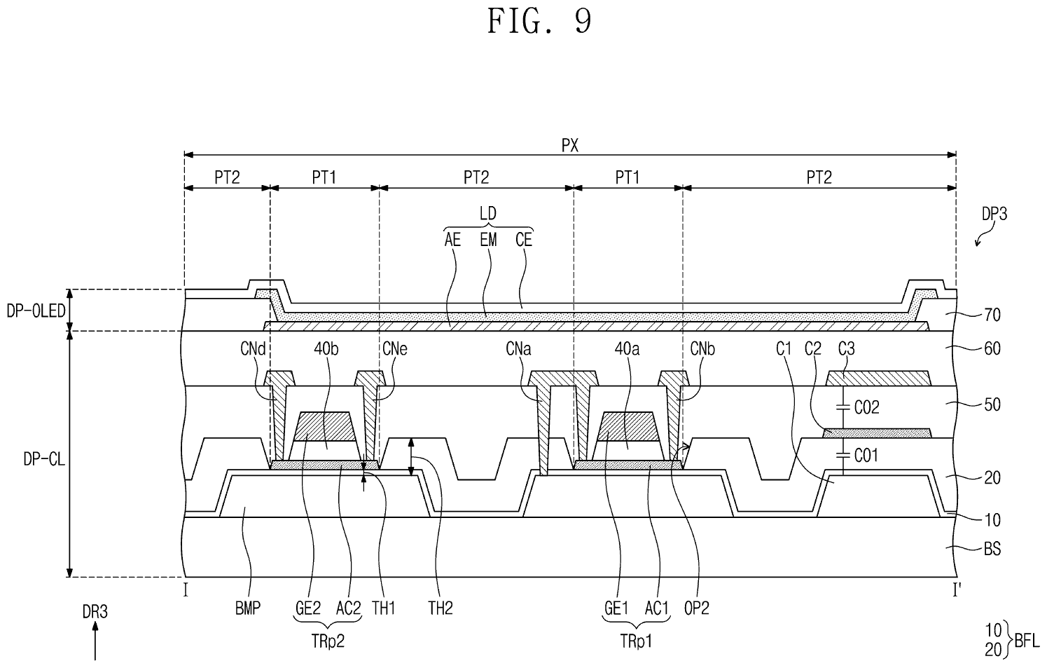

FIG. 9 is a schematic cross-sectional view of a display panel DP3 according to an embodiment of the disclosure. Hereinafter, in a description with reference to FIG. 9, the same/similar reference numerals are used for the same/similar configurations as those described in FIGS. 6 to 8, and a repeated description thereof are omitted.

Referring to FIG. 9, in an embodiment, the buffer layer BFL may include multiple layers. For example, the buffer layer BFL may include first and second insulating layers 10 and 20. Unlike an embodiment illustrated in FIG. 7, the third insulating layer 30 (see FIG. 7) may not be disposed on the second insulating layer.

As illustrated in FIG. 9, an opening OP2 that passes through the second insulating layer 20 may be defined in the buffer layer BFL. The first part PT1 may include a single layer including the first insulating layer 10, and the second part PT2 may include multiple layers, in which the first and second insulating layers 10 and 20 are laminated. However, the disclosure is not limited thereto, and the buffer layer BFL may have various structures as long as the first part PT1 and the second part PT2 having different thicknesses may be included.

The first semiconductor pattern AC1 and the second semiconductor pattern AC2 may be disposed in the first part PT1. The first semiconductor pattern AC1 and the second semiconductor pattern AC2 may be disposed in the opening OP2 and contact the first insulating layer 10.

According to the disclosure, because the first part PT1 of the buffer layer BFL, which has a relatively small thickness, is disposed in an area, in which the semiconductor patterns AC1 and AC2 are disposed, a phenomenon, in which a threshold voltages of the transistors TRp1 and TRp2 is moved in a negative direction, may be prevented, and the driving voltage ranges of the transistors TRp1 and TRp2 may be increased. Furthermore, according to the disclosure, because the second part PT2 of the buffer layer BFL, which has a relatively large thickness, is disposed in an area other than an area, in which the semiconductor pattern constitutes the transistor, are disposed, the lower conductive patterns BMP may be sufficiently covered by the buffer layer BFL. Accordingly, it may be possible to prevent a step coverage issue from occurring due to the thickness of the lower conductive patterns BMP.

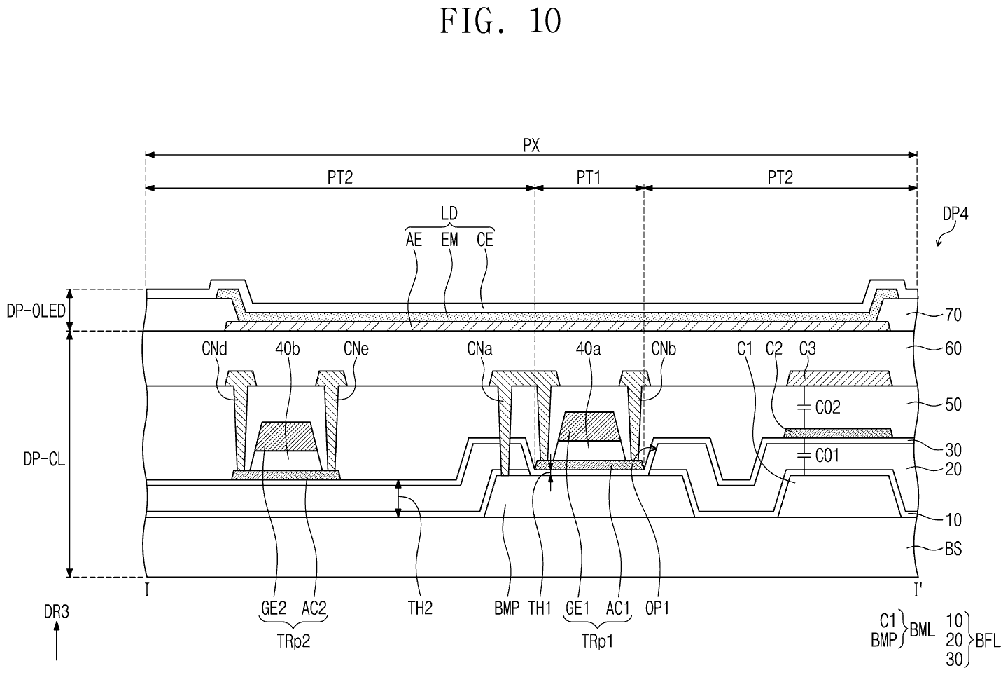

FIG. 10 is a schematic cross-sectional view of a display panel DP4 according to an embodiment of the disclosure. Hereinafter, in a description with reference to FIG. 10, the same/similar reference numerals are used for the same/similar configurations as those described in FIGS. 6A to 9, and a repeated description thereof are omitted.

Referring to FIG. 10, the first transistor TRp1 may overlap the lower conductive patterns BMP in a plan view. The first transistor TRp1 may be disposed in the first part PT1. The first transistor TRp1 may overlap the opening OP1 in a plan view.

The second transistor TRp2 may not overlap the lower conductive patterns BMP in a plan view. The second transistor TRp2 may be disposed on the second part PT2. The second transistor TRp2 may not overlap the opening OP1 in a plan view. For example, the thickness of the buffer layer BFL that overlaps the second transistor TRp2 may be the same as the second thickness TH2, and may be greater than the first thickness TH1. However, the thickness of the buffer layer BFL overlapping the second transistor TRp2 may be variously changed, and is not limited to any one embodiment.

The first semiconductor pattern AC1 may be disposed in the first part PT1. The second semiconductor pattern AC2 may be disposed in the second part PT2. The first semiconductor pattern AC1 may be disposed in the opening OP1. The second semiconductor pattern AC2 may not overlap the lower conductive patterns BMP in a plan view.

According to the disclosure, because the lower conductive pattern BMP is not disposed in the area, in which the second transistor TRp2 is disposed, a possibility of defects between the layers may be reduced compared to the case, in which the lower conductive pattern BMP is disposed. Furthermore, an electrical stress caused by the lower conductive pattern BMP may be reduced, and thus, the reliability of the element may be improved.

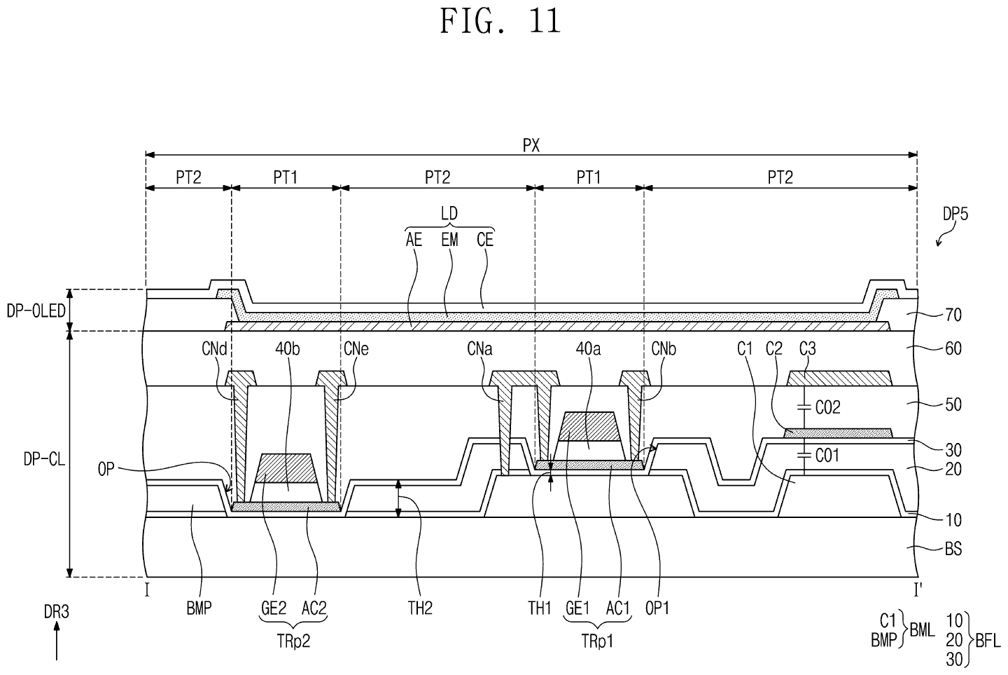

FIG. 11 is a schematic cross-sectional view of a display panel DP5 according to an embodiment of the disclosure. Hereinafter, in a description with reference to FIG. 11, the same/similar reference numerals are used for the same/similar configurations as those described in FIGS. 6 to 10, and a repeated description thereof are omitted.

The first transistor TRp1 may overlap the lower conductive patterns BMP in a plan view. The first transistor TRp1 may be disposed in the first part PT1. The first transistor TRp1 may overlap the opening OP1 in a plan view.

The second transistor TRp2 may not overlap the lower conductive patterns BMP in a plan view. Unlike the embodiment described with reference to FIG. 10, the second transistor TRp2 may be disposed in the first part PT1, and may be disposed in the opening OP1. For example, the thickness of the buffer layer BFL that overlaps the second transistor TRp2 may be the same as the first thickness TH1, and may be smaller than the second thickness TH2. However, the thickness of the buffer layer BFL overlapping the second transistor TRp2 may be variously changed, and is not limited to any one embodiment.

By forming a thickness of the buffer layer BFL that overlaps the second transistor TRp2 thin, a tendency of the threshold voltage to move in a negative direction may be reduced. Furthermore, because the lower conductive patterns BMP are not disposed under the second transistor TRp2, a step coverage issue may not occur in the process of covering the lower conductive patterns even in case that the thickness of the buffer layer BFL that overlaps the second transistor TRp2 is formed thin.

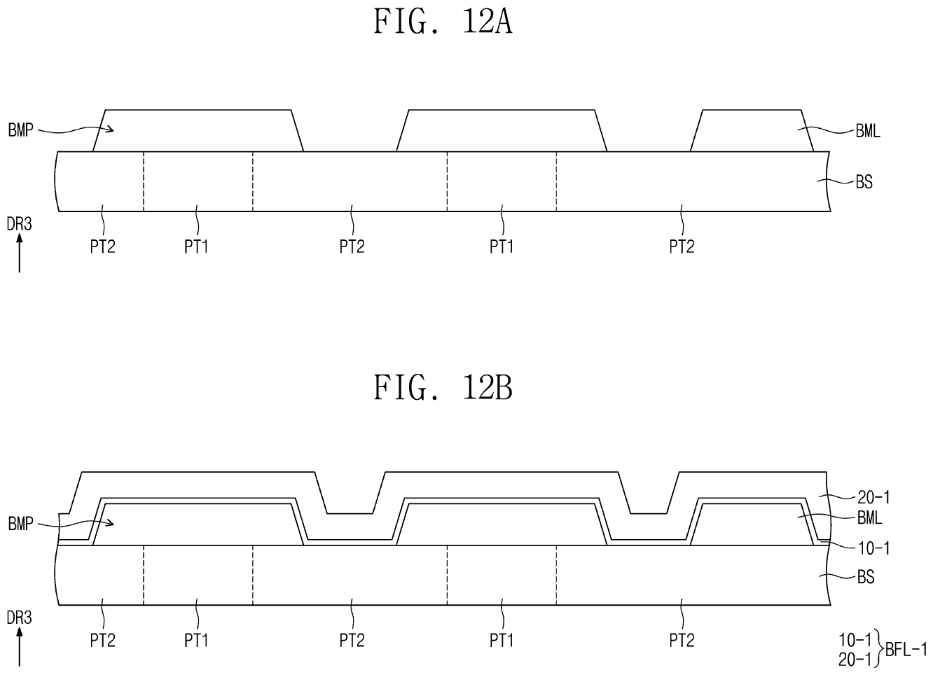

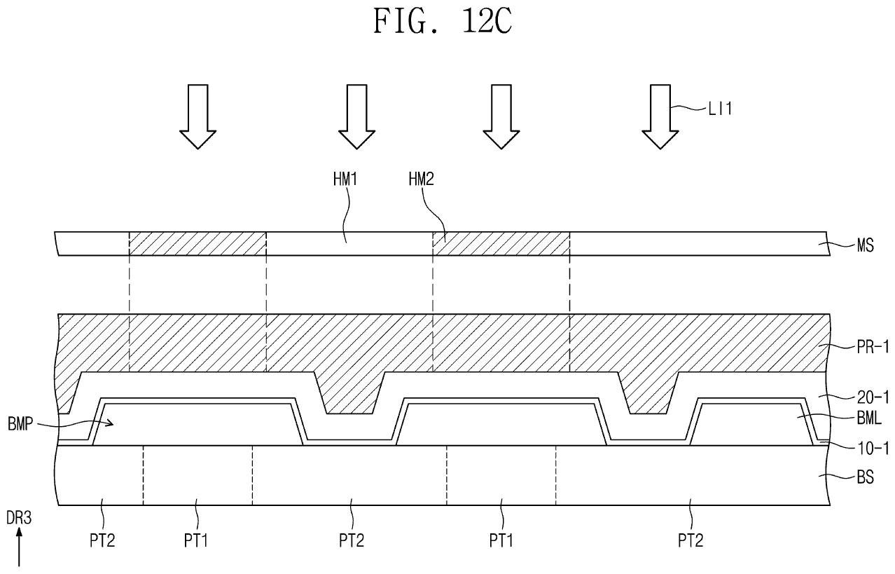

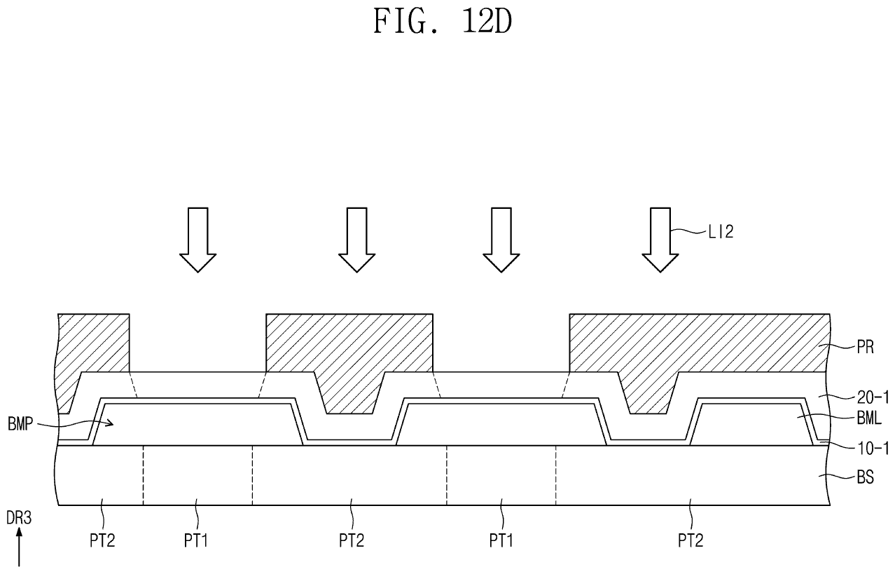

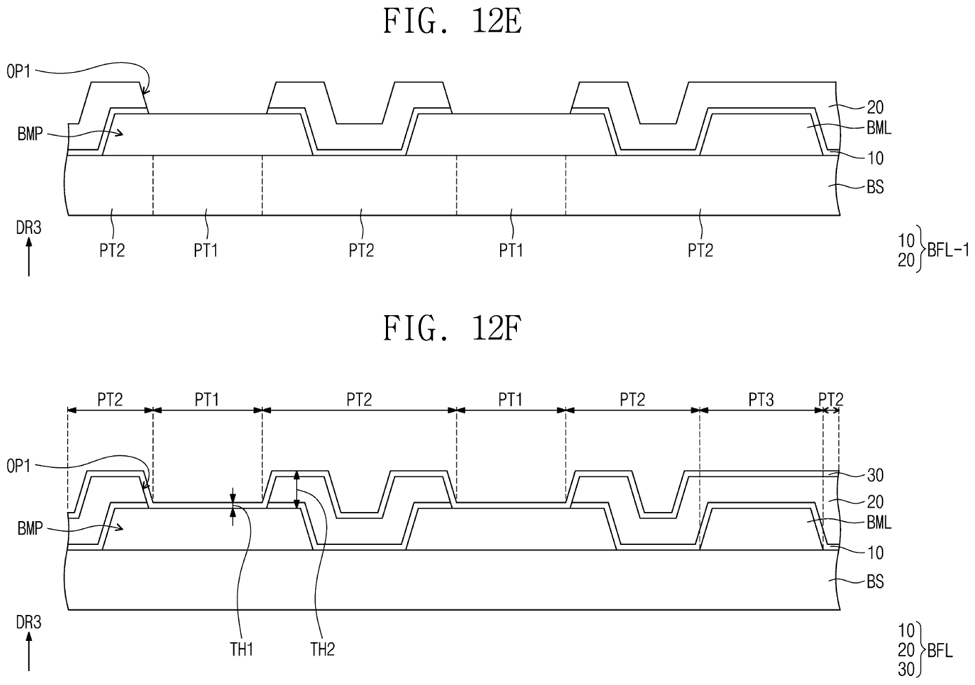

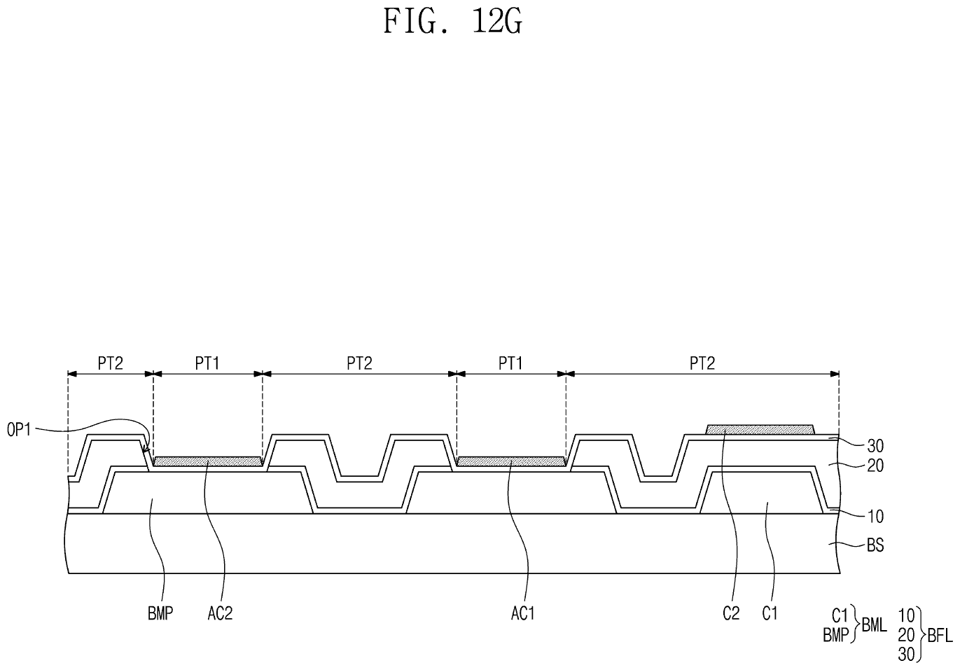

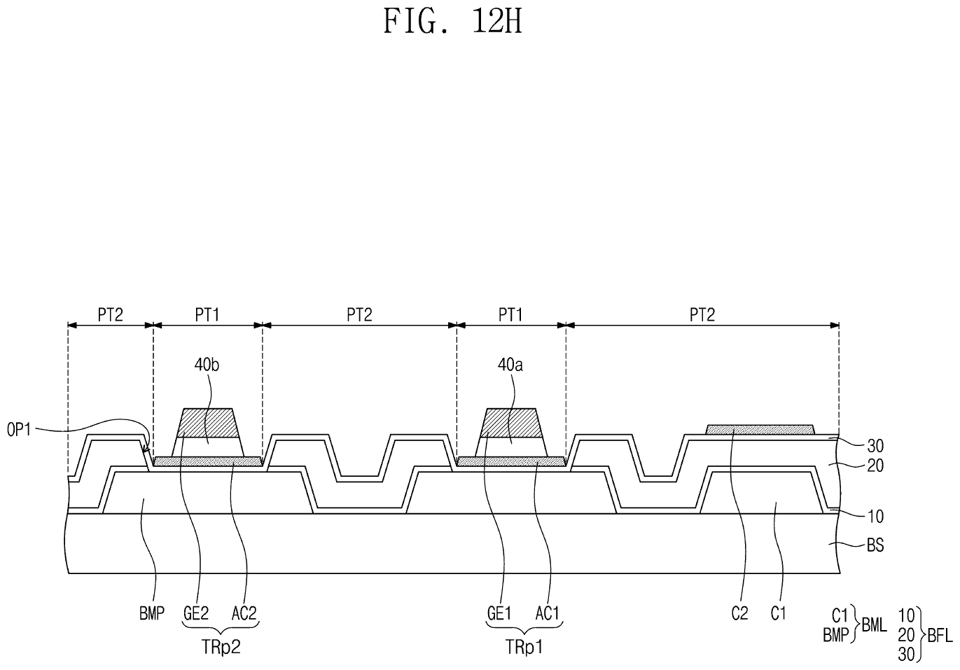

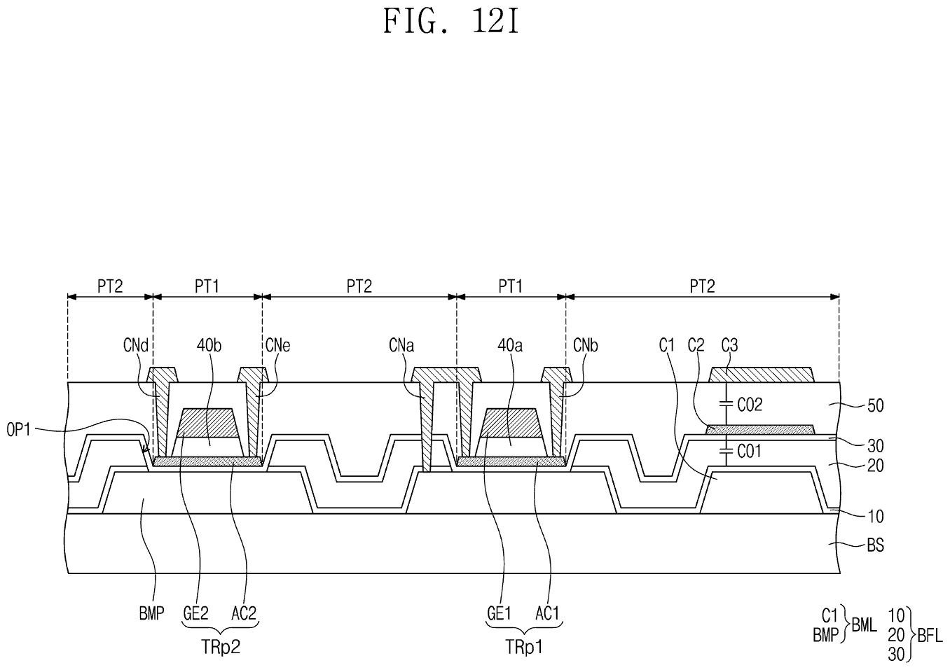

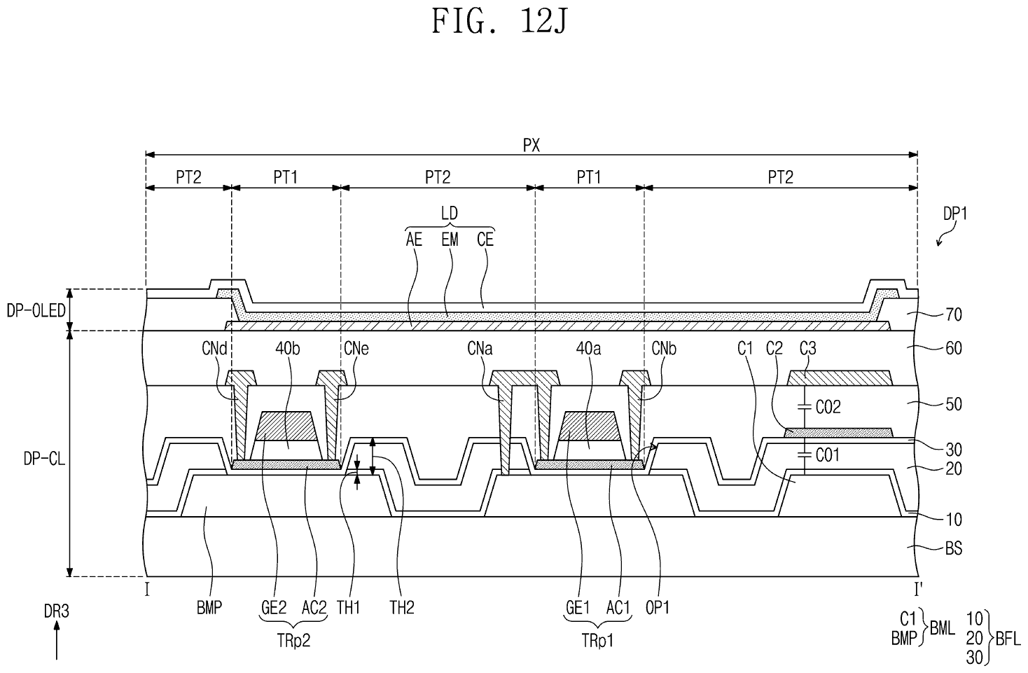

FIGS. 12A to 12I are schematic cross-sectional views illustrating a method for manufacturing a display panel according to an embodiment of the disclosure. Hereinafter, in a description with reference to FIGS. 12A to 12I, the same/similar reference numerals are used for the same/similar configurations as those described in FIGS. 3 to 11, and a repeated description thereof are omitted.

Referring to FIG. 12A, a substrate BS may include a first area PT1 and a second area PT2. The first area PT1 and the second area PT2 may correspond to the first part PT1 and the second part PT2 described above, respectively. A lower conductive layer BML may be formed on the substrate BS. In the lower conductive layer BML, multiple lower conductive patterns BMP that are spaced apart from each other may be formed. The lower conductive patterns BMP may be formed by forming a conductive layer on the substrate BS through deposition or coating, and patterning the conductive layer.

Hereinafter, referring to FIG. 12B, an initial buffer layer BFL-1 may be formed on the lower conductive patterns BMP. The initial buffer layer BFL-1 may be formed by sequentially laminating an initial lower oxide layer 10-1 and an initial nitride layer 20-1. Each of the initial lower oxide layer 10-1 and the initial nitride layer 20-1 may be formed on the entire surface of the substrate BS. The initial lower oxide layer 10-1 may be formed by depositing or coating a material containing silicon oxide. The initial nitride layer 20-1 may be formed by depositing or coating a material containing silicon oxide or silicon oxynitride.

Referring to FIGS. 12C to 12E, multiple openings OP1 may be formed in the initial buffer layer BFL-1. The openings OP1 may be formed by using a photoresist layer PR as a mask. FIG. 12E schematically illustrates a state, in which a photoresist layer PR is removed after at least portions of the initial lower oxide layer 10-1 and the initial nitride layer 20-1 are removed.

Referring to FIGS. 12C and 12D, a photoresist layer PR may be formed by patterning a preliminary photoresist layer PR-1. The preliminary photoresist layer PR-1 may be formed on the initial lower oxide layer 10-1 and the initial nitride layer 20-1.

A mask MS may include a light transmitting part HM1 that transmits light in a specific wavelength band and a light shielding part HM2 that shields irradiated light. The light transmitting part HM1 may overlap the second area PT2 in a plan view. The light transmitting part HM1 may not overlap the lower conductive patterns BMP in a plan view. The light shielding part HM2 may overlap the first area PT1 in a plan view. The light shielding part HM2 may overlap the lower conductive patterns BMP in a plan view.

The photoresist layer PR may be formed by removing a portion of the preliminary photoresist layer PR-1 by irradiating the first light LI1 from a top of the mask MS. In an embodiment, the photoresist layer PR may include a negative photosensitive agent. Accordingly, a portion of the preliminary photoresist layer PR-1, which corresponds to the light transmitting part HM1, remains, and a portion of the preliminary photoresist layer PR-1, which corresponds to the light shielding part HM2, may be removed. For example, the photoresist layer PR may not overlap the first area PT1, and may overlap the second area PT2 in a plan view. However, the disclosure is not limited thereto, and in another embodiment, a positive photosensitive agent (positive-PR), from which the photosensitive portion is removed, may be used for formation of the photoresist layer PR. Furthermore, the photoresist layer PR may be patterned by using semiconductor patterns AC1 and AC2 that will be used in a subsequent process, as a mask without using the mask MS, and is not limited to any one embodiment.

Referring to FIGS. 12D and 12E, at least portions of the initial lower oxide layer 10-1 and the initial nitride layer 20-1 may be removed by irradiating an etching solution LI2 (or an etching gas) onto the photoresist layer PR. At least portions of the initial lower oxide layer 10-1 and the initial nitride layer 20-1 may be removed through an etching process. The initial lower oxide layer 10-1 and the initial nitride layer 20-1 that do not overlap the photoresist layer PR may be etched together to form an opening OP1 that passes through the initial lower oxide layer 10-1 and the initial nitride layer 20-1. For example, the initial lower oxide layer 10-1 and the initial nitride layer 20-1 that overlap the first area PT1 in a plan view may be etched together to form an opening OP1. Accordingly, the upper surfaces of the lower conductive patterns BMP may be exposed.

The material that constitutes the lower conductive patterns BMP and the material that constitutes each of the initial lower oxide layer 10-1 and the initial nitride layer 20-1 may have specific etch selectivities. The etching process may be performed through a dry etching method. However, the disclosure is not limited thereto. In the dry etching process, a mixed gas may be used.

Referring to FIG. 12F, the upper oxide layer 30 may be formed on the nitride layer 20 to form the buffer layer BFL. The upper oxide layer 30 may be formed to overlap the first and second areas PT1 and PT2 of the substrate BS in a plan view. The upper oxide layer 30 may cover the exposed upper surfaces of the lower conductive patterns BMP by removing the lower oxide layer 10 and the nitride layer 20.

The buffer layer BFL may include a first part PT1 and a second part PT2 having different thicknesses. The first part PT1 may have a first thickness TH1. The second part PT2 may have a second thickness TH2. The first thickness TH1 may be smaller than the second thickness TH2. The first part PT1 may be formed of a single layer including the lower oxide layer 10, and the second part PT2 may be formed of multiple layers, in which the lower oxide layer 10, the nitride layer 20, and the upper oxide layer 30 are laminated. However, the disclosure is not limited thereto, and the buffer layer BFL may have various structures as long as the first part PT1 and the second part PT2 having different thicknesses may be included.

Referring to FIG. 12G, semiconductor patterns AC1 and AC2 and a second electrode C2 may be formed on the buffer layer BFL. The semiconductor patterns AC1 and AC2 and the second electrode C2 may be formed by depositing or coating a semiconductor material on the buffer layer BFL and patterning it into multiple patterns. The semiconductor material may include an oxide semiconductor. For example, the semiconductor material may include a transparent conductive oxide (TCO), such as indium-tin oxide (ITO), indium-gallium-zinc oxide (IGZO), zinc oxide (ZnO), zinc-indium oxide (ZnO), indium oxide (InO), titanium oxide (TiO), indium-zinc-tin oxide (IZTO), zinc-tin oxide (ZTO), and the like.

Each of the first semiconductor pattern AC1 and the second semiconductor pattern AC2 may be formed in the first area PT1 of the buffer layer BFL. The first semiconductor pattern AC1 and the second semiconductor pattern AC2 may be patterned from one semiconductor layer using a mask. The first semiconductor pattern AC1 and the second semiconductor pattern AC2 may be disposed in the openings OP1, respectively. The second semiconductor pattern AC2 may be formed to be spaced apart from the first semiconductor pattern AC1. The second electrode C2 may be formed in an area of the second area PT2 of the buffer layer BFL, which overlaps the lower conductive patterns BMP in a plan view.

In an embodiment, although not illustrated, the mask for forming the first semiconductor pattern AC1 and the second semiconductor pattern AC2 may be used for the operating of patterning the initial lower oxide layer 10-1 and the initial nitride layer 20-1. Because the positions, in which the first semiconductor pattern AC1 and the second semiconductor pattern AC2 are formed, substantially correspond to the positions, in which the first parts PT1 are formed, the above-described opening OP1 may be formed in case that the initial lower oxide layer 10-1 and the initial nitride layer 20-1 are patterned by using the mask for forming the first semiconductor pattern AC1 and the second semiconductor pattern AC2. The above-described operation of forming the photoresist layer PR may be omitted, and thus the process may be simplified and the process costs may be reduced. However, the disclosure is not limited thereto, and a method for manufacturing a display panel according to an embodiment of the disclosure may include various process operations as long as the buffer layer BFL having the first part PT1 may be formed.

Referring to FIG. 12H, multiple insulating patterns 40a and 40b and first and second gates GE1 and GE2 may be formed. An insulating material layer may be formed by depositing or coating an insulating material so that the semiconductor patterns AC1 and AC2 and the second electrode C2 are covered on the lower oxide layer 10 and the nitride layer 20. Thereafter, a conductive material may be deposited or coated to form a conductive layer. Thereafter, the first and second gates GE1 and GE2 may be formed by patterning the conductive layer, and the insulating patterns 40a and 40b may be formed by etching the insulating material layer by using the first and second gates GE1 and GE2 as masks.

In an embodiment, areas of the semiconductor patterns AC1 and AC2, which are covered by the insulating patterns 40a and 40b, may be reduced to form a source area and a drain area, respectively. Accordingly, the source area and the drain area of the semiconductor patterns AC1 and AC2 may be self-aligned to the second gate GE2.

Referring now to FIG. 12I, thereafter, a fifth insulating layer 50 may be formed, and multiple connection electrodes CNa, CNb, CNc, and CNd and a third electrode C3 may be formed. The fifth insulating layer 50 may be formed by depositing or coating an insulating material. Thereafter, through-holes may be formed in the fifth insulating layer 50 or the third insulating layer 30 and the fifth insulating layer 50. The connection electrodes CNa, CNb, CNc, and CNd and the third electrode C3 may be formed by forming a conductive layer and patterning the conductive layer. The connection electrodes CNa, CNb, CNd, and CNe may be filled in the corresponding through-holes to be connected to a source area and a drain area of the first semiconductor pattern AC1, and a source area and a drain area of the second semiconductor pattern AC2. The third electrode C3 and the second electrode C2 may form the second capacitor C02.

Referring to FIG. 12J, a display element layer DP-OLED may be formed by forming a seventh insulating layer 70 and a light emitting element LD. The anode AE may be formed by depositing a conductive material to form a conductive layer and patterning the conductive layer. Thereafter, an insulating material may be deposited or coated to form an insulating material layer, and an opening may be formed to form a seventh insulating layer 70. Thereafter, a light emitting element LD may be formed by sequentially forming a light emission layer EM and a cathode CE.

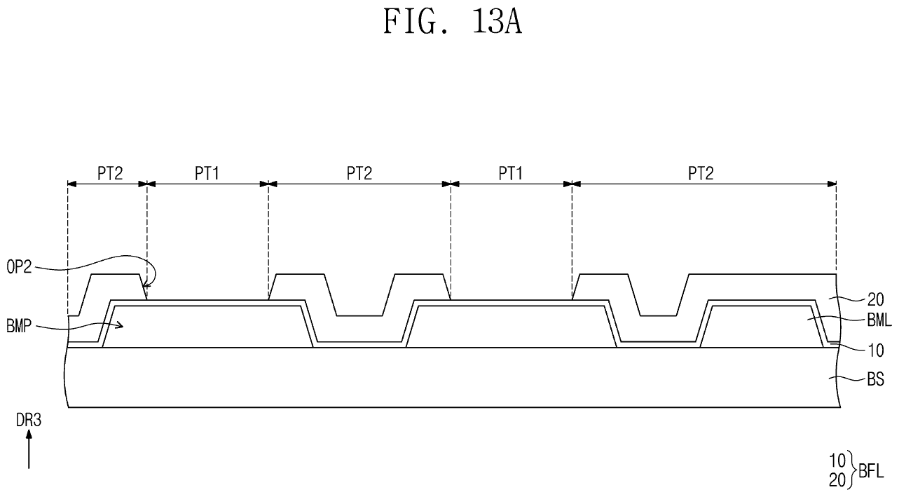

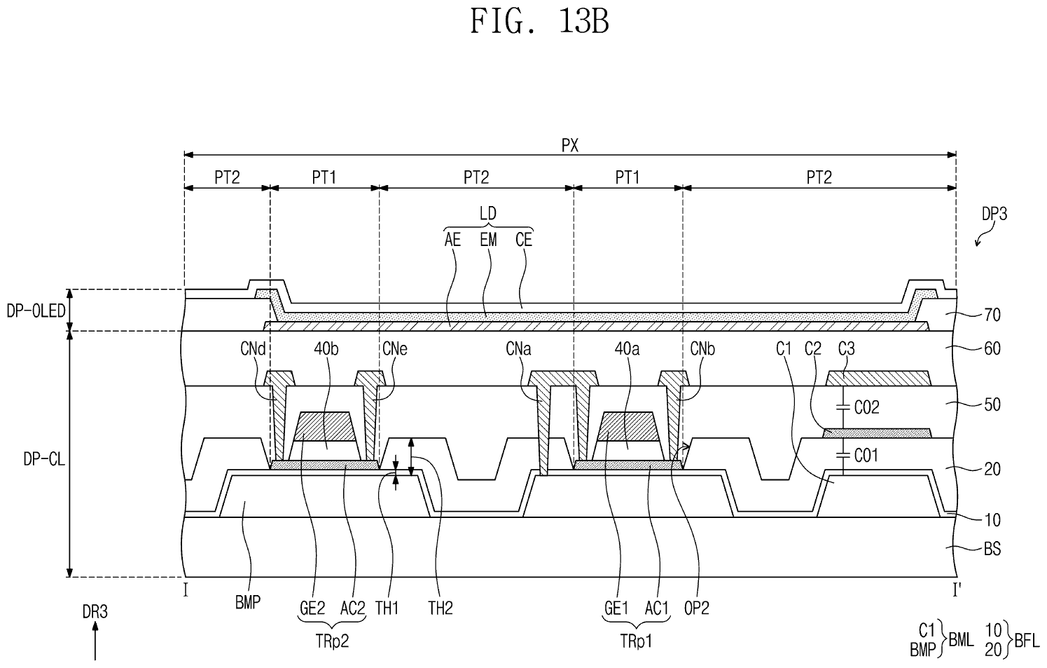

FIGS. 13A and 13B are schematic cross-sectional views illustrating a method for manufacturing a display panel according to an embodiment of the disclosure. Hereinafter, in a description with reference to FIGS. 13A to 13b, the same/similar reference numerals are used for the same/similar configurations as those described in FIGS. 3 to 12I, and a repeated description thereof are omitted.

Referring to FIG. 13A, the lower oxide layer 10 may not be etched in the operation of etching the nitride layer 20. Accordingly, the upper surfaces of the lower oxide layer 10 may be exposed by forming the openings OP2 that overlap the first area PT1 in a plan view in the nitride layer 20. The nitride layer 20 may be formed of a material having a higher etch selectivity with respect to the lower oxide layer 10, and in case that the nitride layer 20 is etched, the opening OP2 may be formed only in the nitride layer 20 and may not be formed in the lower oxide layer 20 by using an etching gas that may be selectively etched only for the nitride layer 20, among the lower oxide layer 10 and the nitride layer 20.

Referring to FIG. 13B, after the operation of removing at least a portion of the lower oxide layer 20, the operation of forming the upper oxide layer 30 on the lower oxide layer 10 and the nitride layer 20 may be omitted. Accordingly, each of the first semiconductor pattern AC1 and the second semiconductor pattern AC2 may be disposed on the lower oxide layer 10 exposed by the opening OP2.

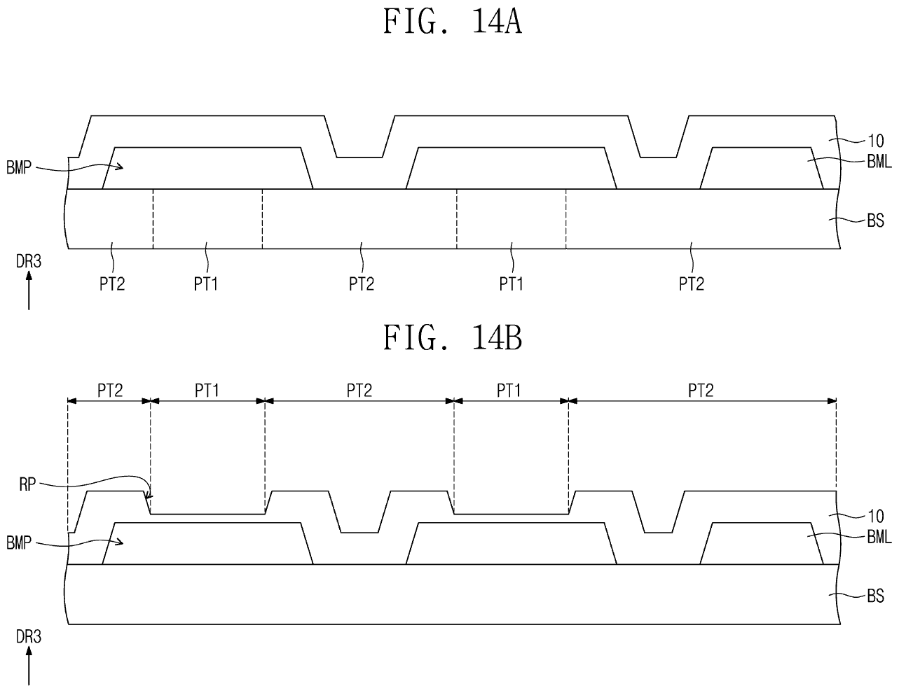

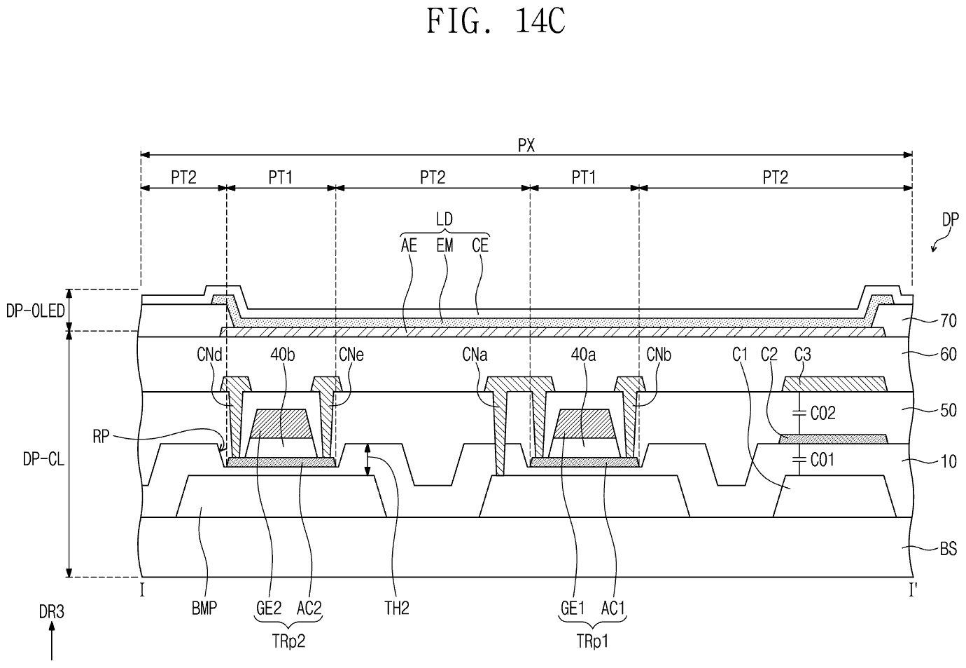

FIGS. 14A to 14C are schematic cross-sectional views illustrating a method for manufacturing a display panel according to an embodiment of the disclosure. Hereinafter, in a description with reference to FIGS. 14A to 14B, the same/similar reference numerals are used for the same/similar configurations as those described in FIGS. 3 to 13B, and a repeated description thereof are omitted.

Referring to FIG. 14A, unlike the above-described embodiments, the buffer layer BFL may be formed as a single layer in an embodiment. The buffer layer BFL (for example, the lower oxide layer 10) may be formed on the entire surface of the substrate BS. The buffer layer BFL may be formed of a material including silicon oxide.

Referring to FIGS. 14B and 14C, at least a portion of the buffer layer BFL, which overlaps the first area PT1 in a plan view, may be removed to form a recessed part RP on the upper surface of the buffer layer BFL.

Each of the first semiconductor pattern AC1 and the second semiconductor pattern AC2 may be formed in the first area PT1 of the buffer layer BFL. Each of the first semiconductor pattern AC1 and the second semiconductor pattern AC2 may be formed in the recessed part RP.

According to the disclosure, an electronic device with an improved reliability may be provided by improving a driving voltage range of the pixel transistor and alleviating a phenomenon, in which a threshold voltage is moved in a negative direction.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. An electronic device comprising:
a first transistor disposed on a substrate and including a first semiconductor pattern and a first gate; and
a buffer layer,
wherein the buffer layer includes:
a first part overlapping the first semiconductor pattern in a plan view and having a first thickness; and
a second part connected to the first part and having a second thickness, the second thickness and the first thickness being different from each other.

2. The electronic device of claim 1, wherein
the buffer layer includes a plurality of layers, and
at least one of the plurality of layers does not overlap the first part in a plan view.

3. The electronic device of claim 2, wherein
the plurality of layers include a lower oxide layer, a nitride layer disposed on the lower oxide layer, and an upper oxide layer disposed on the nitride layer, and
the lower oxide layer and the nitride layer do not overlap the first part in a plan view.

4. The electronic device of claim 3, further comprising:
an opening passing through the lower oxide layer and the nitride layer,
wherein the first semiconductor pattern is disposed in the opening and contacts the upper oxide layer.

5. The electronic device of claim 2, wherein
the plurality of layers include a lower oxide layer and a nitride layer disposed on the lower oxide layer, and
the nitride layer does not overlap the first part in a plan view.

6. The electronic device of claim 5, wherein the first semiconductor pattern contacts the lower oxide layer.

7. The electronic device of claim 2, wherein
the buffer layer is a single layer, and
a recessed part overlapping the first part in a plan view is defined in the buffer layer.

8. The electronic device of claim 7, wherein the buffer layer includes silicon oxide.

9. The electronic device of claim 1, further comprising:
a lower conductive layer including lower conductive patterns disposed on the substrate,
wherein one of the lower conductive patterns is electrically connected to the first semiconductor pattern.

10. The electronic device of claim 9, further comprising:
a second transistor including a second semiconductor pattern spaced apart from the first semiconductor pattern and a second gate overlapping the second semiconductor pattern in a plan view, wherein
the first part includes a plurality of parts spaced apart from each other, and
each of the first semiconductor pattern and the second semiconductor pattern is disposed in one of the plurality of parts.

11. The electronic device of claim 10, wherein another one of the lower conductive patterns overlaps the second semiconductor pattern in a plan view and is insulated from the second semiconductor pattern.

12. The electronic device of claim 10, wherein the second transistor does not overlap the lower conductive patterns in a plan view.

13. The electronic device of claim 12, wherein a thickness of a portion of the buffer layer, which overlaps the second transistor, and the second thickness are different from each other.

14. The electronic device of claim 9, wherein the second part includes a portion overlapping another one of the lower conductive patterns in a plan view.

15. A method for manufacturing an electronic device, the method comprising:
providing a substrate including a first area and a second area;
forming lower conductive patterns on the substrate;
forming an initial buffer layer covering the lower conductive patterns;
forming a buffer layer by removing at least a portion of the initial buffer layer, which overlaps the first area in a plan view such that portions of the lower conductive patterns are exposed;
forming a semiconductor pattern in the first area; and
forming a gate overlapping the semiconductor pattern in a plan view.

16. The method of claim 15, wherein the forming of the buffer layer includes:
forming a recessed part overlapping the first area in a plan view in the buffer layer.

17. The method of claim 15, wherein
the forming of the initial buffer layer includes:
forming a lower oxide layer; and
forming a nitride layer on the lower oxide layer, and
the forming of the buffer layer includes:
forming an opening overlapping the first area in a plan view in the nitride layer.

18. The method of claim 17, wherein a material constituting the lower oxide layer has a higher etch selectivity than a material constituting the nitride layer.

19. The method of claim 17, further comprising:
forming an upper oxide layer on the nitride layer, wherein
the upper oxide layer is formed to overlap the first area and the second area in a plan view, and
the semiconductor pattern is formed by forming a semiconductor material on the upper oxide layer and patterning the semiconductor material such that the semiconductor material overlaps the opening in a plan view.

20. The method of claim 15, wherein the forming of the buffer layer includes:
removing at least a portion of the initial buffer layer in the first area through a dry etching process.
